(19) United States
(12) Patent Application Publication
(10) Pub. No.: US 2025/0203855 A1
(43) Pub. Date: Jun. 19, 2025

(54) SEMICONDUCTOR DEVICES

(71) Applicant: Samsung Electronics Co., Ltd., Suwon-si (KR)

(72) Inventors: Donggyu Heo, Suwon-si (KR); Jaerok Kahng, Suwon-si (KR)

(21) Appl. No.: 18/817,409

(22) Filed: Aug. 28, 2024

(30) Foreign Application Priority Data
Dec. 18, 2023 (KR) 10-2023-0184448

(51) Int. Cl. H10B 12/00

(52) U.S. Cl. CPC H10B 12/50; H10B 12/315

(57) ABSTRACT

A semiconductor device includes an integrated circuit structure including conductive regions; a capacitor including first electrode structures electrically connected to the conductive regions of the integrated circuit structure, a dielectric layer on the first electrode structures, and a second electrode structure on the dielectric layer; an insulating blocking layer on at least a portion of a surface of the second electrode structure; and an interconnection region on the insulating blocking layer and including a conductive pattern and an insulating structure, wherein the insulating structure includes etch stop layers and interlayer insulating layers that are stacked with one another, wherein at least one of the interlayer insulating layers includes hydrogen, and wherein the insulating blocking layer includes a different material from the etch stop layers.

### CROSS-REFERENCE TO RELATED APPLICATIONS

The application claims benefit of priority to Korean Patent Application No. 10-2023-0184448 filed on Dec. 18, 2023 in the Korean Intellectual Property Office, the disclosure of which is incorporated herein by reference in its entirety.

### BACKGROUND OF THE INVENTION

Example embodiments of the present disclosure relate to a semiconductor device.

As demand for high performance, high speed, and/or multifunctionality for a semiconductor device increases, integration density of a semiconductor device has increased. Accordingly, it may be beneficial to develop a technique to reduce structural defects present in a semiconductor device.

### SUMMARY OF THE INVENTION

Example embodiments of the present disclosure provide a semiconductor device including a hydrogen diffusion prevention layer on a capacitor and in a redistribution region.

According to some example embodiments, a semiconductor device includes an integrated circuit structure including conductive regions; a capacitor including first electrode structures electrically connected to the conductive regions of the integrated circuit structure, a dielectric layer on the first electrode structures, and a second electrode structure on the dielectric layer; an insulating blocking layer on at least a portion of a surface of the second electrode structure; and an interconnection region on the insulating blocking layer and including a conductive pattern and an insulating structure, wherein the insulating structure includes etch stop layers and interlayer insulating layers that are stacked with one another, wherein at least one of the interlayer insulating layers includes hydrogen, and wherein the insulating blocking layer includes a different material from the etch stop layers.

According to some example embodiments, a semiconductor device includes a capacitor; a lower interlayer insulating layer on the capacitor; a lower contact extending into the lower interlayer insulating layer and electrically connected to the capacitor; an interconnection region on the lower contact and the lower interlayer insulating layer, the interconnection region including an insulating structure and an interconnection structure in the insulating structure, wherein the insulating structure includes etch stop layers and first interlayer insulating layers that are stacked with one another; a first passivation layer on the interconnection region; a redistribution region on the first passivation layer and including a second interlayer insulating layer and a redistribution structure on the second interlayer insulating layer; a second passivation layer on the redistribution region; an upper passivation layer on the second passivation layer; and an upper blocking layer on at least one of an upper surface or a lower surface of the second passivation layer.

According to some example embodiments, a semiconductor device includes a substrate including a cell array region and a peripheral circuit region; a lower blocking layer in contact with at least a portion of a side surface of a capacitor, wherein the capacitor is on the cell array region of the substrate; a peripheral transistor on the peripheral circuit region of the substrate; a lower interlayer insulating layer on the lower blocking layer and the peripheral transistor; a cell lower contact extending into the lower interlayer insulating layer and electrically connected to the capacitor; a peripheral lower contact extending into the lower interlayer insulating layer and electrically connected to the peripheral transistor; an interconnection region on the lower interlayer insulating layer, the interconnection region including a lower structure including a lower insulating structure and lower conductive patterns in the lower insulating structure, wherein the lower insulating structure includes etch stop layers and low-K layers alternately stacked on the cell lower contact, the peripheral lower contact, and the lower interlayer insulating layer; and an upper structure including an upper interlayer insulating layer on the lower structure and an upper conductive pattern in the upper interlayer insulating layer, wherein the upper conductive pattern is electrically connected to the lower conductive patterns, a first passivation layer on the interconnection region; a redistribution region on the first passivation layer, the redistribution region including a hydrogen supply material layer on the first passivation layer; and a redistribution structure including a redistribution layer on the hydrogen supply material layer and a redistribution via extending into the hydrogen supply material layer, the first passivation layer, and the upper interlayer insulating layer, wherein the redistribution via electrically connects the redistribution layer to the upper conductive pattern, a second passivation layer on the redistribution region; an upper passivation layer on the second passivation layer; and an upper blocking layer on at least one of an upper surface or a lower surface of the second passivation layer and extending on the cell array region and the peripheral circuit region.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan diagram illustrating a semiconductor device according to some example embodiments of the present disclosure;

FIG. 2 is an enlarged diagram illustrating a portion of the semiconductor device illustrated in FIG. 1;

FIG. 3 is a vertical cross-sectional diagram illustrating the semiconductor device illustrated in FIG. 1 taken along line I-I′;

FIGS. 4A and 4B are enlarged diagrams illustrating a portion of the semiconductor device illustrated in FIG. 3;

FIG. 5 is a vertical cross-sectional diagram illustrating the semiconductor device illustrated in FIG. 1 taken along line II-II′;

FIGS. 6A and 6B are enlarged diagrams illustrating a portion of the semiconductor device illustrated in FIGS. 3 and 5;

FIGS. 7A, 7B, 8A, 8B, 9A, 9B, 10A, 10B, 11A, 11B, 12A, 12B, 13A, 13B, 14A, 14B, 15A, 15B, 16A, 16B, 17A, and 17B are vertical cross-sectional diagrams illustrating processes of a method of manufacturing a semiconductor device in order according to some example embodiments of the present disclosure;

FIG. 18 is a layout diagram illustrating a semiconductor device according to some example embodiments of the present disclosure; and

FIG. 19 is a cross-sectional diagram illustrating a semiconductor device according to some example embodiments of the present disclosure.

### DETAILED DESCRIPTION

Hereinafter, example embodiments of the present disclosure will be described as follows with reference to the accompanying drawings.

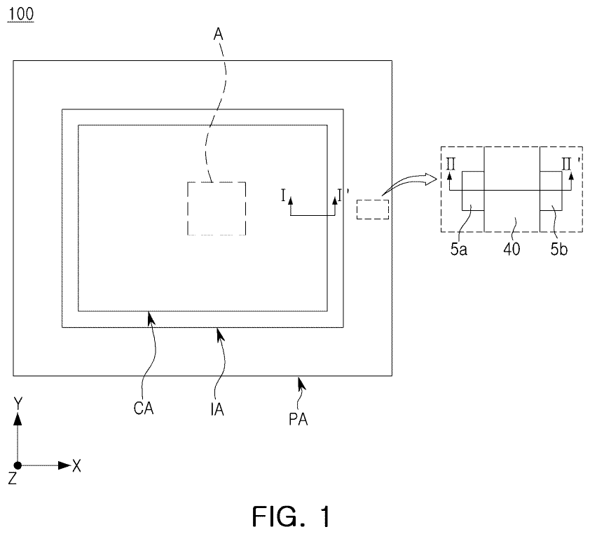

FIG. 1 is a plan diagram illustrating a semiconductor device according to some example embodiments.

Referring to FIG. 1, a semiconductor device according to some example embodiments may include a cell region CA (which may also be referred to as a cell array region), an interface region IA, and a peripheral circuit region PA. The peripheral circuit region PA may be disposed to surround the cell region CA, and the interface region IA may be disposed between the cell region CA and the peripheral circuit region PA. The cell region CA may refer to a region in which memory cells of a dynamic random access memory (DRAM) device are disposed, and the peripheral circuit region PA may be a region in which a wordline driver, a sense amplifier, row and column decoders and control circuits are disposed. The interface region IA may be a region for electrically connecting the cell region CA to the peripheral circuit region PA.

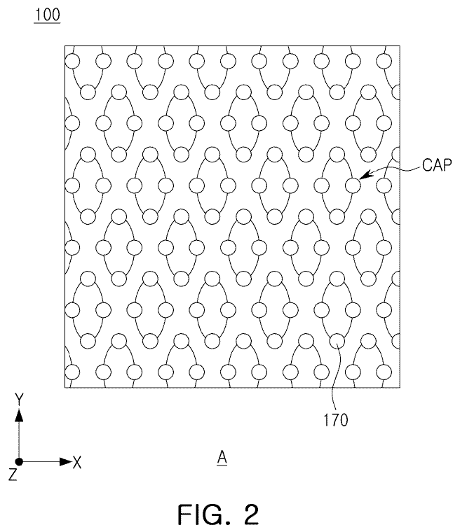

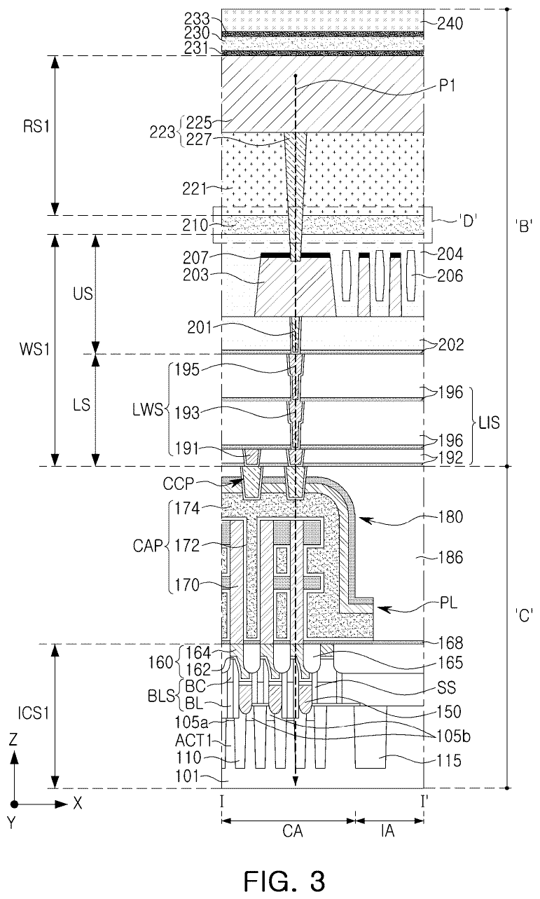

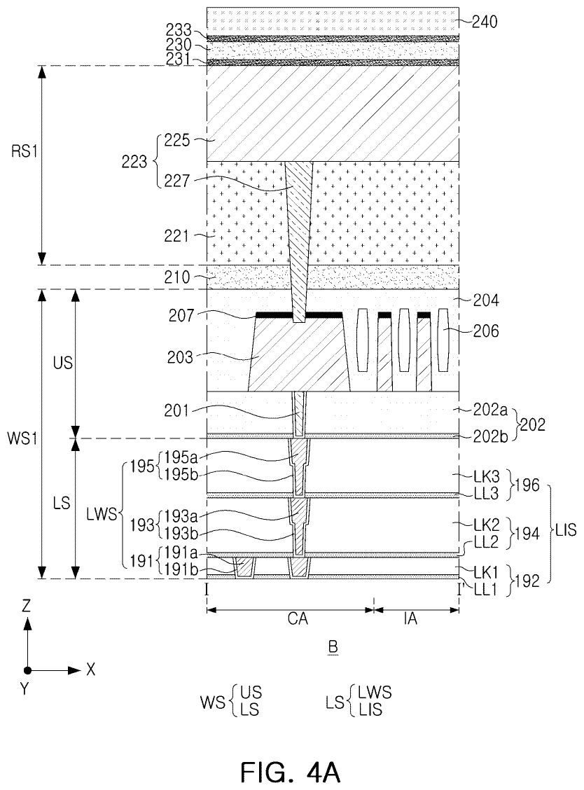

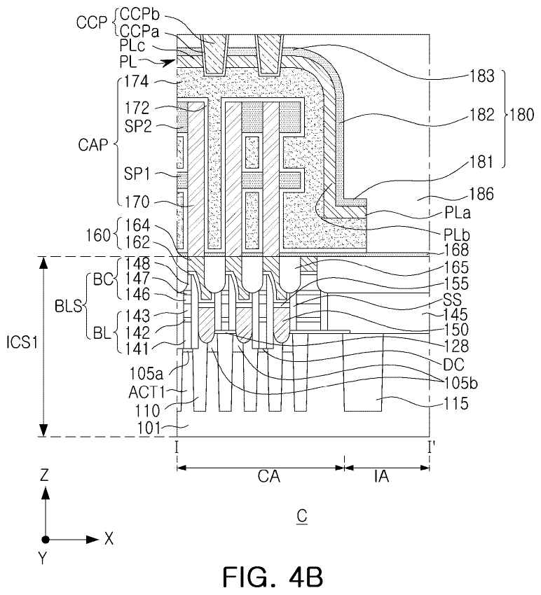

FIG. 2 is an enlarged diagram illustrating a portion of the semiconductor device illustrated in FIG. 1. FIG. 3 is a vertical cross-sectional diagram illustrating the semiconductor device illustrated in FIG. 1 taken along line I-I′. FIGS. 4A and 4B are enlarged diagrams illustrating a portion of the semiconductor device illustrated in FIG. 3, corresponding to regions B and C of the semiconductor device illustrated in FIG. 3, respectively.

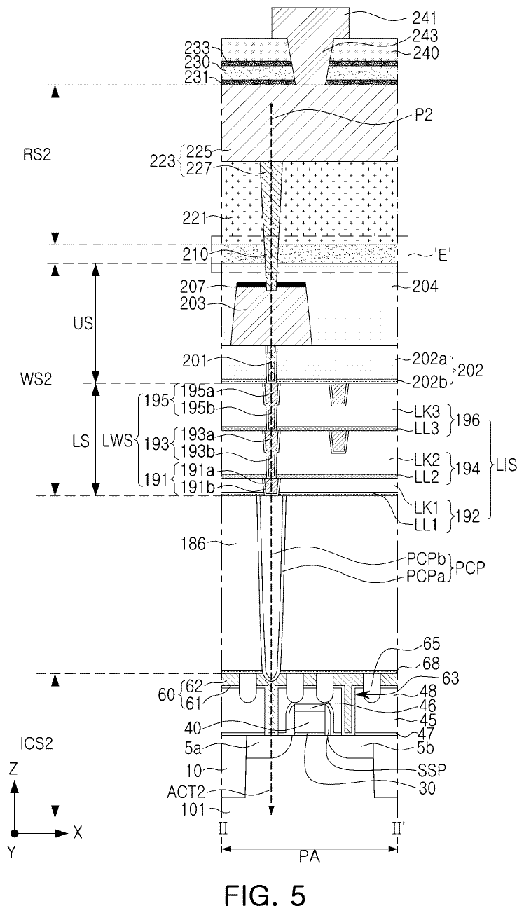

Referring to FIGS. 2, 3, 4A, and 4B, a semiconductor device 100 may include an integrated circuit region ICS throughout the cell region CA and the peripheral circuit region PA. The integrated circuit region ICS may include a cell integrated circuit region ICS1 (or ‘cell integrated circuit structure’) having a plurality of cell transistors and/or circuits on the cell region CA, and a peripheral integrated circuit region ICS2 (or ‘peripheral integrated circuit structure’) having a plurality of peripheral transistors and/or circuits on the peripheral circuit region PA (e.g., see FIG. 5).

The semiconductor device 100 may include, in the cell integrated circuit region ICS1, a substrate 101 including first active regions ACT1, a device isolation layer 110 defining first active regions ACT1 in the substrate 101, a bitline structure BLS disposed on the substrate 101 and including the bitline BL, a data storage structure CAP on the bitline structure BLS, a plate layer PL on the data storage structure CAP, and a blocking layer 180 on the plate layer PL. The data storage structure CAP may store data, and may be configured as the capacitor structure of DRAM, for example. In the cell integrated circuit region ICS1, the semiconductor device 100 may further include a lower conductive pattern 150 on the first active region ACT1, an upper conductive pattern 160 on the lower conductive pattern 150, and an insulating pattern 165 penetrating (i.e., extending into) the upper conductive pattern 160. The semiconductor device 100 may further include a wordline disposed in the cell region CA and embedded in the substrate 101.

The semiconductor device 100 may include, for example, a cell array of dynamic random access memory (DRAM). For example, the bitline BL may be connected to the first impurity region 105a of the first active region ACT1, and the second impurity region 105b of the first active region ACT1 may be electrically connected to the data storage structure CAP on the upper conductive pattern 160 through the lower and upper conductive patterns 150 and 160.

The data storage structure CAP may be a capacitor which may store data in a memory such as a DRAM. The data storage structure CAP may be electrically connected to conductive regions 150 and 160 on a lower structure including lower and upper conductive patterns 150 and 160, for example. Here, the lower structure may include the substrate 101, the wordline, and the bitline structure BLS.

The data storage structure CAP may include first electrode structures 170, a dielectric layer 172 on the first electrode structures 170, and a second electrode structure 174 on the dielectric layer 172. The data storage structure CAP may further include supporter layers SP1 and SP2. The first electrode structures 170 may be configured as lower electrodes, and the second electrode structures 174 may be configured as upper electrodes.

The substrate 101 may include a semiconductor material, such as a group IV semiconductor, a group III-V compound semiconductor, or a group II-VI compound semiconductor. For example, a group IV semiconductor may include silicon, germanium, or silicon-germanium. The substrate 101 may further include impurities. The substrate 101 may be implemented as a silicon substrate, a silicon on insulator (SOI) substrate, a germanium substrate, a germanium on insulator (GOI) substrate, a silicon-germanium substrate, or a substrate including an epitaxial layer.

The first active regions ACT1 may be defined in the substrate 101 by a device isolation layer 110. The first active region ACT1 may have first and second impurity regions 105a and 105b at a predetermined depth from an upper surface of the substrate 101. The first and second impurity regions 105a and 105b may be spaced apart from each other. The first and second impurity regions 105a and 105b may be provided as a source/drain region of a transistor formed by the wordline. The source region and the drain region may be formed by the first and second impurity regions 105a and 105b by doping or ion implantation of substantially the same impurities, and may be referred to interchangeably depending on a circuit component of the transistor finally formed. The impurities may include impurities having a conductivity-type opposite to that of the substrate 101. In some example embodiments, depths of the first and second impurity regions 105a and 105b in the source region and the drain region may be different.

The device isolation layer 110 may be formed by a shallow trench isolation (STI) process. The device isolation layer 110 may surround the first active regions ACT1 and may electrically separate the regions from each other. The device isolation layer 110 may be formed of an insulating material, for example, silicon oxide, silicon nitride, or a combination thereof. It will be understood that “an element A surrounds an element B” (or similar language) as used herein means that the element A is at least partially around the element B but does not necessarily mean that the element A completely encloses the element B.

The wordline may be disposed to extend in the first direction X throughout the first active region ACT1. For example, a pair of adjacent wordlines may be disposed to cross the first active region ACT1. A wordline may be included in a gate of a buried channel array transistor (BCAT), but the present disclosure is not limited thereto.

The bitline structure BLS may extend perpendicularly to the wordline in one direction, for example, in the second direction Y. The bitline structure BLS may include a bitline BL and a bitline capping pattern BC on the bitline BL. The first direction X and the second direction Y may be substantially parallel to a lower surface of the substrate 101.

The bitline BL may include the first conductive pattern 141, the second conductive pattern 142, and the third conductive pattern 143, stacked in order. The bitline capping pattern BC may be disposed on the third conductive pattern 143. A buffer insulating layer 128 may be disposed between the first conductive pattern 141 and the substrate 101, and a portion (hereinafter, bitline contact pattern DC) of the first conductive pattern 141 may be in contact with the first impurity region 105a of the first active region ACT1. The bitline BL may be electrically connected to the first impurity region 105a through the bitline contact pattern DC. A lower surface of the bitline contact pattern DC may be disposed on a level lower than a level of an upper surface of the substrate 101, and may be disposed on a level higher than a level of an upper surface of the wordline. In some example embodiments, the bitline contact pattern DC may be formed in the substrate 101 and may be locally disposed in a bitline contact hole exposing the first impurity region 105a. As used herein, the term “level” refers to a height in a vertical direction (i.e., the third direction Z) from a lower surface of the substrate 101. The third direction Z may be substantially perpendicular to the lower surface of the substrate 101.

The first conductive pattern 141 may include a semiconductor material such as polycrystalline silicon. The first conductive pattern 141 may be in direct contact with the first impurity region 105a. The second conductive pattern 142 may include a metal-semiconductor compound. For example, the metal-semiconductor compound may be obtained by siliciding a portion of the first conductive pattern 141. For example, the metal-semiconductor compound may include cobalt silicide (CoSi), titanium silicide (TiSi), nickel silicide (NiSi), tungsten silicide (WSi), or other metal silicide. The third conductive pattern 143 may include a metal material such as titanium (Ti), tantalum (Ta), tungsten (W), and aluminum (Al). The number of conductive patterns included in the bitline BL, a type of material of the conductive patterns, and/or the stacking order thereof may be varied in example embodiments.

The bitline capping pattern BC may include a first capping pattern 146, a second capping pattern 147, and a third capping pattern 148 stacked in order on the third conductive pattern 143. Each of the first to third capping patterns 146, 147, and 148 may include an insulating material, for example, a silicon nitride film. The first to third capping patterns 146, 147, and 148 may be formed of different materials, and even when the patterns include the same material, boundaries may be distinct due to differences in physical properties. A thickness of the second capping pattern 147 may be smaller than thicknesses of the first capping pattern 146 and the third capping pattern 148 (e.g., in the third direction Z). The number of capping patterns and/or a type of material forming the bitline capping pattern BC may be varied in example embodiments.

The spacer structures SS may be disposed on both (i.e., opposing) sidewalls of each of the bitline structures BLS and may extend in one direction, for example, the Y-direction. The spacer structures SS may be disposed between the bitline structure BLS and the lower conductive pattern 150. The spacer structures SS may be disposed to extend along sidewalls of the bitline BL and the sidewalls of the bitline capping pattern BC. A pair of spacer structures SS disposed on both sides of the bitline structure BLS may have an asymmetric shape with respect to the bitline structure BLS. Each of the spacer structures SS may include a plurality of spacer layers, and may further include air spacers in some example embodiments.

The lower conductive pattern 150 may be connected to one region of the first active region ACT1, for example, the second impurity region 105b. The lower conductive pattern 150 may be disposed between the bitlines BL. The lower conductive pattern 150 may penetrate the buffer insulating layer 128 and may be connected to the second impurity region 105b of the first active region ACT1. The lower conductive pattern 150 may be in direct contact with the second impurity region 105b. A lower surface of the lower conductive pattern 150 may be disposed on a level lower than a level of an upper surface of the substrate 101, and may be disposed on a level higher than a level of a lower surface of the bitline contact pattern DC. The lower conductive pattern 150 may be insulated from the bitline contact pattern DC by the spacer structure SS. The lower conductive pattern 150 may be formed of a conductive material, for example, at least one of polycrystalline silicon (Si), titanium (Ti), titanium nitride (TiN), tantalum (Ta), tantalum nitride (TaN), tungsten (W), tungsten nitride (WN) or aluminum (Al). In some example embodiments, the lower conductive pattern 150 may include multiple layers. As used herein, “an element A connected to an element B” (or similar language) means that the element A is physically and/or electrically connected to the element B.

The metal-semiconductor compound layer 155 may be disposed between the lower conductive pattern 150 and the upper conductive pattern 160. For example, when the lower conductive pattern 150 includes a semiconductor material, the metal-semiconductor compound layer 155 may be obtained by siliciding a portion of the lower conductive pattern 150. The metal-semiconductor compound layer 155 may include, for example, cobalt silicide (CoSi), titanium silicide (TiSi), nickel silicide (NiSi), tungsten silicide (WSi), or other metal silicide. In other example embodiments, the metal-semiconductor compound layer 155 may not be provided.

The upper conductive pattern 160 may be disposed on the lower conductive pattern 150. The upper conductive pattern 160 may extend to a region between the spacer structures SS and may be on (e.g., may cover) an upper surface of the metal-semiconductor compound layer 155. The upper conductive pattern 160 may include a barrier layer 162 and a conductive layer 164. The barrier layer 162 may be on (e.g., may cover) a lower surface and side surfaces of the conductive layer 164. The barrier layer 162 may include at least one of metal nitride, such as titanium nitride (TiN), tantalum nitride (TaN), and tungsten nitride (WN). The conductive layer 164 may include a conductive material, for example, at least one of polycrystalline silicon (Si), titanium (Ti), tantalum (Ta), tungsten (W), ruthenium (Ru), copper (Cu), molybdenum (Mo), platinum (Pt), nickel (Ni), cobalt (Co), aluminum (Al), titanium nitride (TiN), tantalum nitride (TaN), and tungsten nitride (WN).

The insulating patterns 165 may be disposed to penetrate the upper conductive pattern 160. The upper conductive pattern 160 may be divided into multiple portions by the insulating patterns 165. The insulating patterns 165 may include at least one of an insulating material, for example, silicon oxide, silicon nitride, and silicon oxynitride.

The etch stop layer 168 may be on (e.g., may cover) the insulating patterns 165 between the first electrode structures 170. The etch stop layer 168 may also extend further into an interface region IA. The etch stop layer 168 may be in contact with a lower region of side surfaces of the first electrode structures 170. The etch stop layer 168 may be disposed below supporter layers SP1 and SP2. An upper surface of the etch stop layer 168 may include a portion in direct contact with the dielectric layer 172. For example, the etch stop layer 168 may include at least one of silicon nitride or silicon oxynitride.

The first electrode structures 170 may be disposed on the upper conductive patterns 160. The first electrode structures 170 may penetrate the etch stop layer 168 and may be in contact with the upper conductive patterns 160. The first electrode structures 170 may have a pillar shape, but the present disclosure is not limited thereto. The first electrode structures 170 may include at least one of niobium nitride (NbN), niobium oxide (NbOx), polycrystalline silicon (Si), iridium (Ir), titanium (Ti), titanium nitride (TiN), titanium silicide nitride (TiSiN), tantalum (Ta), tantalum nitride (TaN), tungsten (W), tungsten nitride (WN), and aluminum (Al), or a combination thereof, metal nitride, metal compound, or the like.

The dielectric layer 172 may be on (e.g., may cover) a side surface and an upper surface of each of the first electrode structures 170 on a surface of the first electrode structures 170. The dielectric layer 172 may be disposed between the first electrode structures 170 and the second electrode structures 174. The dielectric layer 172 may be on (e.g., may cover) upper surfaces and lower surfaces of the support layers SP1 and SP2. The dielectric layer 172 may be on (e.g., may cover) an upper surface of the etch stop layer 168.

The dielectric layer 172 may include a high-K material, silicon oxide, silicon nitride, or a combination thereof. In some example embodiments, the dielectric layer 172 may include at least one of Fluorine (F)-doped titanium (Ti), tantalum (Ta), hafnium (Hf), aluminum (Al), zirconium (Zr), and lanthanum (La), or oxide, nitride, silicide, oxynitride, or silicified oxynitride, including combinations thereof.

The second electrode structure 174 may be disposed on the dielectric layer 172. The second electrode structure 174 may fill a space between the plurality of first electrode structures 170 and a space between supporter layers SP1 and SP2. In some example embodiments, the dielectric layer 172 and the second electrode structure 174 may further extend to the interface region IA. The second electrode structure 174 may include a conductive material.

The second electrode structure 174 may include a single layer or multiple layers. In some example embodiments, the second electrode structure 174 may be in direct contact with the dielectric layer 172 and may include a first material layer formed along the dielectric layer 172 and a second material layer on (e.g., covering) the first material layer. The first material layer may include a doped semiconductor, metal, conductive metal nitride, metal-semiconductor compound, conductive metal oxide, or a combination thereof. The second material layer may include a silicon material or a silicon-germanium material. For example, the second material layer may include a doped silicon material or a doped silicon-germanium material.

In some example embodiments, the second electrode structure 174 may further include a protective material layer which may prevent natural oxidation of the second electrode structure 174 and oxidation by the dielectric layer 172. For example, the protective material layer may be covered by the first material layer and may be in direct contact with the dielectric layer 172. The protective material layer may include at least one of metal, metal-silicon oxide, metal-silicon nitride, or metal-silicon oxynitride.

The supporter layers SP1 and SP2 may include the first supporter layer SP1 and the second supporter layer SP2 on the first supporter layer SP1. The support layers SP1 and SP2 may be spaced apart from the substrate 101 in a direction perpendicular to an upper surface of the substrate 101 (e.g., the Z-direction). The supporter layers SP1 and SP2 may be in contact with the first electrode structures 170 and may extend in a direction parallel to an upper surface of the substrate 101.

The supporter layers SP1 and SP2 may support the first electrode structures 170 having a high aspect ratio. Each of the support layers SP1 and SP2 may include, for example, at least one of silicon nitride, silicon oxynitride, or materials similar thereto. The number of the support layers SP1 and SP2, a thickness of the support layers SP1 and SP2 and/or dispositional relationship between the layers are not limited to the illustrated examples and may vary in example embodiments.

Referring to FIG. 2, the first electrode structures 170 may have a regular arrangement in the plan diagram, viewed from above. In example embodiments, the first electrode structures 170 may be spaced apart from each other by a predetermined distance in the first direction X, and may be disposed in a zigzag pattern in the second direction Y. For example, the first electrode structures 170 may be disposed in a honeycomb structure. However, the arrangement of the first electrode structures 170 is not limited thereto.

A through-hole pattern may be disposed between the plurality of adjacent first electrode structures 170. In some example embodiments, as illustrated in the semiconductor device 100 in FIG. 2, a through-hole pattern may be disposed between four adjacent first electrode structures 170. However, the through-hole pattern is not limited thereto.

Referring to FIGS. 2, 3, 4A, and 4B, the plate layer PL may be disposed on the data storage structure CAP. For example, the plate layer PL may be formed conformally along a surface of the second electrode structure 174 of the data storage structure CAP. The plate layer PL may function as the data storage structure CAP together with the second electrode structure 174 of the data storage structure CAP. In other words, the plate layer PL may be a component included in the second electrode structure 174 (i.e., may be considered as part of the second electrode structure 174). In this case, the second electrode structure 174 may also be referred to as the first electrode material layer, and the plate layer PL may also be referred to as the second electrode material layer disposed on the first electrode material layer.

In some example embodiments, the plate layer PL may include a lower portion PLa, an upper portion PLc, and an intermediate portion PLb connecting the lower portion PLa to the upper portion PLc. The upper portion PLc may refer to a portion of the plate layer PL disposed on a level higher than a level of an upper surface of the second electrode structure 174. For example, the upper portion PLc may be on upper surfaces of the first electrode structures 170.

The lower portion PLa may extend in a horizontal direction on the second electrode structure 174. The intermediate portion PLb may extend vertically along a side surface of the second electrode structure 174 from one end of the lower portion PLa. The intermediate portion PLb may extend in a direction perpendicular to the lower portion Pla as in the drawing, but the present disclosure is not limited thereto. In some example embodiments, the intermediate portion PLb may extend in a direction oblique to the Z direction or may extend to have a wavy shape. A portion of the intermediate portion PLb may extend to be rounded (i.e., curved) and may be connected to the upper portion PLc.

The plate layer PL may include a conductive material. For example, the plate layer PL may include tungsten (W).

The blocking layer 180 (or ‘lower blocking layer’) may be on (e.g., may partially cover) the plate layer PL. For example, the blocking layer 180 may be on (e.g., may cover) surfaces of an upper portion PLc and an intermediate portion PLb of the plate layer PL, and a side surface of the lower portion PLa of the plate layer PL may not be covered by the blocking layer 180. The blocking layer 180 may be formed conformally along a surface of the plate layer PL, and a thickness of the blocking layer 180 may be smaller than a thickness of the plate layer PL. The blocking layer 180 may include an insulating material, for example, an insulating material having a low hydrogen diffusivity. The blocking layer 180 may include, for example, aluminum oxide (AlOx). In this case, the blocking layer 180 may be referred to as an insulating blocking layer.

The blocking layer 180 may include a lower portion 181, an upper portion 183, and an intermediate portion 182 connecting the lower portion 181 to the upper portion 183. The lower portion 181 of the blocking layer 180 may extend in the horizontal direction on the lower portion PLa of the plate layer PL. The intermediate portion 182 may extend vertically from one end of the lower portion 181 along a side surface of the intermediate portion PLb of the plate layer PL. The intermediate portion 182 may extend in a direction perpendicular to the lower portion 181 as in the drawing, but the present disclosure is not limited thereto. In some example embodiments, the intermediate portion 182 may extend in a direction oblique to the Z direction or may extend to have a wavy shape. In some example embodiments, in the blocking layer 180, a side surface of the lower portion 181 and a side surface of the lower portion PLa of the plate layer PL may be coplanar with each other. Also, the blocking layer 180 (e.g., the lower portion 181) may be coplanar with a portion of the second electrode structure 174 and the dielectric layer 172. The upper portion 183 of the blocking layer 180 may extend horizontally from one end of the intermediate portion 182 along a surface of the upper portion PLc of the plate layer PL. For example, the upper portion 183 may be on an upper surface of the data storage structure CAP. By disposing the blocking layer 180 on the plate layer PL, hydrogen contained in the lower interlayer insulating layer 186 may be prevented from excessively diffusing to the data storage structure CAP. In this case, the blocking layer 180 may be referred to as a hydrogen diffusion prevention layer. In other words, the blocking layer 180 may be configured to inhibit hydrogen included in the lower interlaye insulating layer 186 from diffusing to the data storage structure CAP. For example, the blocking layer 180 may include a material that has a low hydrogen diffusivity. Accordingly, a fail-bit counts (FBC) occurring when evaluating operation of the semiconductor device 100 may be reduced.

The semiconductor device 100 may further include a lower interlayer insulating layer 186 on (e.g., covering) the plate layer PL and the blocking layer 180. The lower interlayer insulating layer 186 may be on (e.g., may cover) the blocking layer 180. The lower interlayer insulating layer 186 may be in contact with a side surface of the lower portion PLa of the plate layer PL, the second electrode structure 174 and the dielectric layer 172. The lower interlayer insulating layer 186 may include silicon oxide, silicon nitride, silicon oxynitride, or a combination thereof. In some example embodiments, the lower interlayer insulating layer 186 may include silicon oxide. An upper surface of the lower interlayer insulating layer 186 may be flat (i.e., planar), and may be parallel to an upper surface of the substrate 101, for example. The lower interlayer insulating layer 186 may be configured as a hydrogen-containing insulating layer including hydrogen. The lower interlayer insulating layer 186 may include, for example, boro-phosphosilicate glass (BPSG), Tonen Silazene (TOSZ), undoped silicate glass (USG), spin-on glass (SOG), flowable oxide (FOX), tetraethyl orthosilicate (TEOS), high density plasma CVD dielectric, (HDP CVD dielectric), or hydrogen silsesquioxane (HSQ).

The semiconductor device 100 may further include a cell contact plug CCP (or ‘cell lower contact plug’) disposed on the plate layer PL. The cell contact plug CCP may penetrate the lower interlayer insulating layer 186, and may be connected to the data storage structure CAP. For example, the cell contact plug CCP may penetrate the plate layer PL and may be connected to the second electrode structure 174. A lower surface of the cell contact plug CCP may be disposed on a level lower than a level of an upper surface of the second electrode structure 174. An upper surface of the cell contact plug CCP may be coplanar with an upper surface of the lower interlayer insulating layer 186. The cell contact plug CCP may have a barrier layer CCPa and a conductive layer CCPb on the barrier layer CCPa. A side surface of the cell contact plug CCP may be in contact with the lower interlayer insulating layer 186. The conductive layer CCPb may include W, and the barrier layer CCPa may include at least one of Ti, Ta, TiN and TaN.

The semiconductor device 100 may include an interconnection region WS disposed throughout the cell region CA and the peripheral circuit region PA and a redistribution region RS on the interconnection region WS. The interconnection region WS of the cell region CA may be referred to as a cell interconnection region WS1, and the interconnection region WS of the peripheral circuit region PA may be referred to as a peripheral interconnection region WS2 (e.g., see FIG. 5). Similarly, the redistribution region RS of the cell region CA may be referred to as a cell redistribution region RS1, and the redistribution region RS of the peripheral circuit region PA may be referred to as a peripheral redistribution region RS2 (e.g., see FIG. 5).

The cell interconnection region WS1 may be configured to include a plurality of interconnections connected to a plurality of cell transistors and/or circuits of the cell region CA. The cell interconnection region WS1 may include a lower structure LS disposed on the cell contact plug CCP, and an upper structure US disposed on the lower structure LS.

The lower structure LS may include a lower interconnection structure LWS including a plurality of lower conductive patterns and a lower insulating structure LIS including a plurality of lower insulating patterns. For example, the lower interconnection structure LWS may include first, second, and third lower conductive patterns 191, 193, and 195. The first lower conductive pattern 191 may include a first interconnection material layer 191a and a first barrier material layer 191b on (e.g., covering) a side surface and a bottom surface of the first interconnection material layer 191a. The second lower conductive pattern 193 may include a second interconnection material layer 193a and a second barrier material layer 193b disposed on the first lower conductive pattern 191 and on (e.g., covering) a side surface and a bottom surface of the second interconnection material layer 193a. The third lower conductive pattern 195 may be disposed on the second lower conductive pattern 193 and may include a third interconnection material layer 195a and a third barrier material layer 195b on (e.g., covering) a side surface and a bottom surface of the third interconnection material layer 195a. Each of the first, second, and third interconnection material layers 191a, 193a, and 195a may include Cu, and each of the first, second, and third barrier material layers 191b, 193b, and 195b may include at least one of Ti, Ta, TiN, or TaN.

The lower insulating structure LIS may include first, second, and third lower insulating patterns 192, 194, and 196. The first lower insulating pattern 192 may include a first interfacial layer LL1 (or ‘first etch stop layer’) and a first low-K layer LK1 on the first interfacial layer LL1, the second lower insulating pattern 194 may include a second interfacial layer LL2 (or ‘second etch stop layer’) and a second low-K layer LK2 on the second interfacial layer LL2, and the third lower insulating pattern 196 may include a third interfacial layer LL3 (or ‘third etch stop layer’) and a third low-K layer LK3 on the third interfacial layer LL3. Each of the first, second, and third interfacial layers LL1, LL2, and LL3 may be configured as an etch stop layer. Each of the first, second, and third interfacial layers LL1, LL2, and LL3 may include, for example, at least one of SiN, SiCN, or hydrogenated silicon oxycarbide (e.g., SiOCH). Each of the first to third low-K layers LK1, LK2, and LK3 may be configured as an insulating layer including a material with a low dielectric constant. Each of the first to third low-K layers LK1, LK2, and LK3 may include, for example, silicon oxide or a low-K dielectric.

The first lower conductive pattern 191 may be a lower interconnection penetrating the first lower insulating pattern 192 and electrically connected to the cell contact plug CCP. For example, a lower portion of the first lower conductive pattern 191 may penetrate the first interfacial layer LL1 and may be in contact with the conductive layer CCPb of the cell contact plug CCP.

The second lower conductive pattern 193 may be configured as a lower interconnection penetrating the second lower insulating pattern 194 and electrically connected to the first lower conductive pattern 191. For example, a lower portion of the second lower conductive pattern 193 may penetrate the second interfacial layer LL2 and may be in contact with the first interconnection material layer 191a of the first lower conductive pattern 191. Here, a lower portion of the second lower conductive pattern 193 may have a form of a via extending downwardly from a portion of a lower surface of the upper portion.

The third lower conductive pattern 195 may be configured as a lower interconnection penetrating the third lower insulating pattern 196 and electrically connected to the second lower conductive pattern 193. For example, a lower portion of the third lower conductive pattern 195 may penetrate the third interfacial layer LL3 and may be in contact with the second interconnection material layer 193a of the second lower conductive pattern 193. Here, a lower portion of the third lower conductive pattern 195 may have a form of a via extending downwardly from a portion of a lower surface of the upper portion.

The upper structure US may include a plurality of upper interlayer insulating layers 202 and 204, and an upper contact plug 201 and an upper interconnection 203 penetrating at least a portion of the upper interlayer insulating layers.

For example, the upper structure US may penetrate the first upper interlayer insulating layer 202, with the first upper interlayer insulating layer 202 disposed on the lower structure LS, and may include an upper contact plug 201 electrically connected to the third lower conductive pattern 195. The first upper interlayer insulating layer 202 may include an upper interfacial layer 202b (or ‘fourth etch stop layer’) disposed on the third low-K layer LK3 and an upper insulating layer 202a on the upper interfacial layer 202b, and a lower portion of the upper contact plug 201 may penetrate the upper interfacial layer 202b and may be in contact with the third interconnection material layer 195a of the third lower conductive pattern 195. The upper contact plug 201 may include a barrier layer and a conductive layer on the barrier layer. The conductive layer may include a material the same as or similar to that of the conductive layer CCPb of the cell lower contact plug CCP, and the barrier layer may include a material the same as or similar to the barrier layer CCPa of the cell lower contact plug CCP.

The upper structure US may further include an upper interconnection 203 penetrating the second upper interlayer insulating layer 204, with the second upper interlayer insulating layer 204 disposed on the first upper interlayer insulating layer 202, and electrically connected to the upper contact plug 201. The upper interconnection 203 may include a conductive material different from the interconnection material layers 191a, 193a, and 195a of the lower interconnection patterns 191, 193, and 195, for example, Al or W. An upper pad 207 may be further disposed on the upper interconnection 203. The upper pad 207 may include at least one of Ti, Ta, TiN or TaN. A plurality of air gaps 206 may be present in the second upper interlayer insulating layer 204. The plurality of air gaps 206 may be disposed between the upper interconnections 203.

Each of the first and second upper interlayer insulating layers 202 and 204 may be a hydrogen-containing insulating layer including hydrogen. Each of the first and second upper interlayer insulating layers 202 and 204 may include, for example, boro-phosphosilicate glass (BPSG), Tonen Silazene (TOSZ), undoped silicate glass (USG), spin-on glass (SOG), flowable oxide (FOX), tetraethyl orthosilicate (TEOS), high density plasma CVD dielectric (HDP CVD dielectric), or hydrogen silsesquioxane (HSQ). The lower insulating structure LIS and the first and second upper interlayer insulating layers 202 and 204 may also be referred to as an insulating structure.

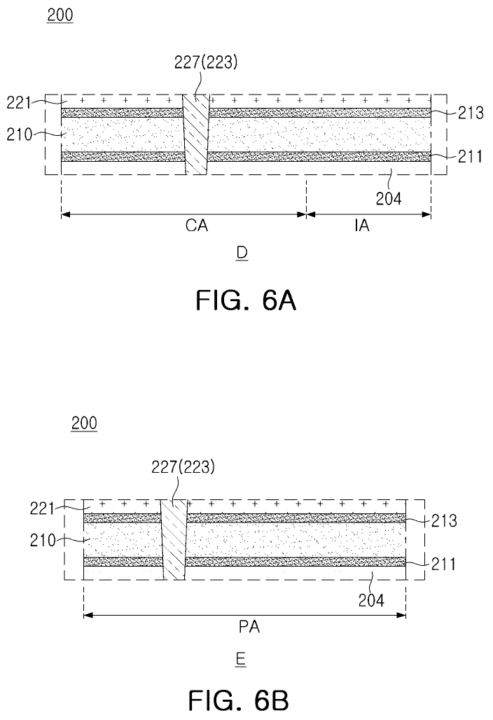

The semiconductor device 100 may further include a first passivation layer 210 between the cell interconnection region WS1 and the redistribution region RS. The first passivation layer 210 may include a material having a relatively low hydrogen diffusivity. For example, the first passivation layer 210 may include at least one of SiN or SiCN. In some example embodiments, blocking layers 211 and 213 (or ‘intermediate blocking layers’) including a material having a hydrogen diffusivity lower than that of the first passivation layer 210 may be further disposed on an upper surface and a lower surface of the first passivation layer 210, which will be described in greater detail later with reference to FIGS. 6A and 6B.

The redistribution region RS may include a plurality of redistributions redistributing the plurality of interconnections of the cell interconnection region WS1. The redistribution region RS may include a hydrogen supply material layer 221 disposed on the cell interconnection region WS1 and a redistribution structure 223 disposed on the hydrogen supply material layer 221.

The hydrogen supply material layer 221 may be an insulating layer including a material having excellent hydrogen concentration and/or hydrogen supply ability. Here, hydrogen may be a hydrogen atom or a concept including hydrogen molecules. The hydrogen-containing insulating layer 221 may include, for example, boro-phosphosilicate glass (BPSG), Tonen Silazene (TOSZ), undoped silicate glass (USG), spin-on glass (SOG), flowable oxide (FOX), tetraethyl orthosilicate (TEOS), high density plasma CVD dielectric (HDP CVD dielectric), or hydrogen silsesquioxane (HSQ).

Redistribution structure 223 may include a redistribution layer 225 and a redistribution via 227. The redistribution via 227 may penetrate at least a portion of the hydrogen supply material layer 221, the first passivation layer 210, and the upper interlayer insulating layer 204, and may electrically connect the redistribution layer 225 to the upper interconnection 203. When the upper pad 207 is disposed on the upper interconnection 203, the redistribution via 227 may also penetrate the upper pad 207. Each of the redistribution layer 225 and the redistribution via 227 may include Al or W.

The semiconductor device 100 may include a second passivation layer 230 on the redistribution region RS. The second passivation layer 230 may include a material the same as or similar to the first passivation layer 210. For example, the second passivation layer 230 may include at least one of SiN or SiCN.

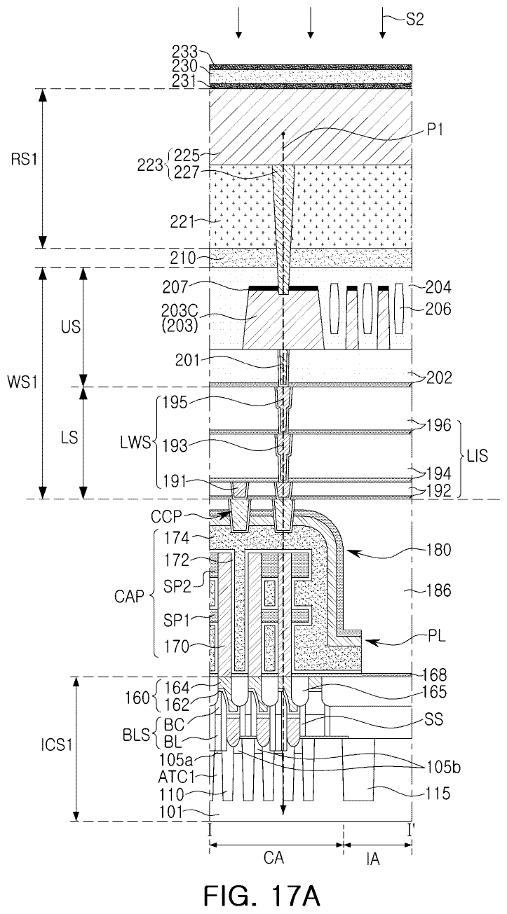

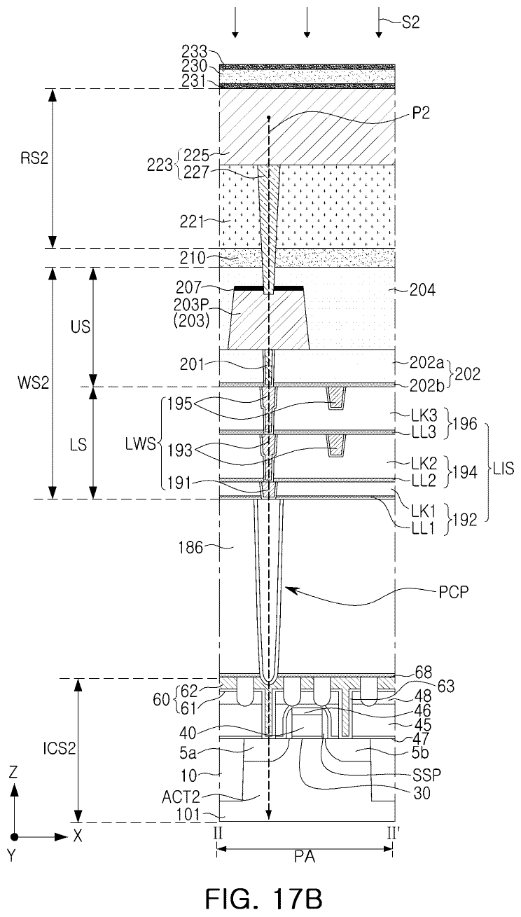

The upper blocking layers 231 and 233 on (e.g., covering) at least one of an upper surface or a lower surface of the second passivation layer 230 may be disposed. For example, the upper blocking layers 231 and 233 may include a first upper blocking layer 231 on (e.g., covering) a lower surface of the second passivation layer 230 and a second upper blocking layer 233 on (e.g., covering) an upper surface of the second passivation layer 230. The first and second upper blocking layers 231 and 233 may include a material having a lower hydrogen diffusivity than that of the second passivation layer 230. The first and second upper blocking layers 231 and 233 may include, for example, aluminum oxide (AlOx). The first and second upper blocking layers 231 and 233 having a low hydrogen diffusivity may be disposed on a lower surface and an upper surface of the second passivation layer 230, and by adding an annealing process, the semiconductor device 100 having improved electrical properties and reliability may be provided. Referring to FIG. 17A, by adding a second annealing process S2, the hydrogen supply material layer 221 may be used as an additional hydrogen supply source. Here, the further disposed first and second upper blocking layers 231 and 233 may completely supply and guide hydrogen derived from the hydrogen supply material layer 221 to the cell transistor through the first hydrogen delivery path P1. The first and second upper blocking layers 231 and 233 may be configured to inhibit hydrogen included in the hydrogen supply material layer 221 from diffusing upwardly (e.g., in a direction away from the cell transistor). For example, the first and second upper blocking layers 231 and 233 may include a material that has a low hydrogen diffusivity. Accordingly, a structural defect present in a silicon crystal of the transistor, for example, a decrease in data retention time may be prevented by supplying hydrogen to a dangling bond, thereby providing the semiconductor device 100 having improved electrical properties and reliability. Here, hydrogen may be supplied to the cell transistor through redistribution layer 225, the redistribution via 227, the upper interconnection 203, the upper contact plug 201, the plurality of lower interconnections 191, 193, and 195, and the lower contact plug CCP, but the supply is not limited to the above path and hydrogen may be supplied through various paths.

Referring back to FIGS. 2, 3, 4A, and 4B, the semiconductor device 100 may further include a third passivation layer 240 (or ‘upper passivation layer’) on the second passivation layer 230. The third passivation layer 240 may include a solder resist including epoxy resin or polyurethane resin. However, the present disclosure is not limited thereto. For example, the third passivation layer 240 may include a photoimageable solder resist (PSR) including a photosensitive resin composition.

The semiconductor device 100 may further include a device isolation layer 115 disposed in the substrate 101 in the interface region IA and an interlayer insulating layer 145 disposed on the substrate 101. The device isolation layer 110 may include a material the same as that of the device isolation layer 115. The interlayer insulating layer 145 may be on (e.g., may cover) the substrate 101 and may include silicon oxide.

FIG. 5 is a vertical cross-sectional diagram illustrating the semiconductor device illustrated in FIG. 1 taken along line II-II′.

Referring to FIG. 5, the semiconductor device 100 may further include a device isolation layer 10, a second active region ACT2, a first peripheral impurity region 5a and a second peripheral impurity region 5b in a peripheral integrated circuit region ICS2 of a peripheral circuit region PA. The device isolation layer 10 may be configured as an insulating layer extending downwardly from an upper surface of substrate 101 and may define the second active region ACT2. The first peripheral impurity region 5a and the second peripheral impurity region 5b may be spaced apart from each other with the peripheral gate structure 40 interposed therebetween.

The device isolation layer 10 may include silicon oxide, silicon nitride, silicon oxynitride, or a combination thereof, and may include a single layer or multiple layers. The first and second peripheral impurity regions 5a and 5b may be provided as source/drain regions of a transistor (i.e., a peripheral transistor) formed by the peripheral gate structure 40. The first and second peripheral impurity regions 5a and 5b may include impurities having a conductivity-type opposite to that of the substrate 101.

The semiconductor device 100 may further include a peripheral gate dielectric layer 30 and a peripheral gate structure 40 disposed on the substrate 101 in the peripheral circuit region PA. The peripheral gate structure 40 may have a structure similar to that of a bitline BL and may be formed of a material similar to that of the bitline BL.

The peripheral gate structure 40 may include a first conductive pattern, a second conductive pattern, and a third conductive pattern stacked in order on the peripheral gate dielectric layer 30 on the substrate 101. The peripheral gate dielectric layer 30 may include silicon oxide, silicon nitride, or a high-k material. The high-K material may refer to a dielectric material having a dielectric constant higher than that of silicon oxide. The first conductive pattern, the second conductive pattern and the third conductive pattern of the peripheral gate structure 40 may include the same materials as those of the first conductive pattern 141, the second conductive pattern 142 and the third conductive pattern 143 of the bitline BL, respectively. The first peripheral capping pattern 46 may be disposed on the peripheral gate structure 40. The first peripheral capping pattern 46 may include the same material as that of the first capping pattern 146 of a bitline capping pattern BC.

The semiconductor device 100 may further include a peripheral gate spacer SSP, a second peripheral capping pattern 47, an interlayer insulating layer 45 and a third peripheral capping pattern 48 in the peripheral circuit region PA. The peripheral gate spacer SSP may be on (e.g., may cover) a side surface of the peripheral gate structure 40. For example, the peripheral gate spacers SSP may be spaced apart from each other with the peripheral gate structure 40 interposed therebetween, and may be on (e.g., may cover) side surfaces of the first conductive pattern, the second conductive pattern, and the third conductive pattern of the peripheral gate structure 40 and side surfaces of the first peripheral capping pattern 46.

The second peripheral capping pattern 47 may be on (e.g., may cover) the substrate 101, the peripheral gate spacer SSP, and the peripheral gate structure 40, and may be formed conformally. The interlayer insulating layer 45 may be on (e.g., may partially cover) the second peripheral capping pattern 47. An upper surface of the interlayer insulating layer 45 may be coplanar with an upper surface of the second peripheral capping pattern 47. The third peripheral capping pattern 48 may be on (e.g., may cover) the interlayer insulating layer 45 and the second peripheral capping pattern 47.

The second peripheral capping pattern 47 and the third peripheral capping pattern 48 may include the same materials as those of the second capping pattern 147 and the third capping pattern 148 of the bitline capping pattern BC, respectively, and may include, for example, silicon nitride. The interlayer insulating layer 45 may include silicon oxide.

The semiconductor device 100 may further include a peripheral plug 63 and a peripheral interconnection 60 electrically connected to the first and second peripheral impurity regions 5a and 5b in the peripheral circuit region PA. The peripheral plugs 63 may penetrate the interlayer insulating layer 45 and may be disposed adjacent to the peripheral gate structure 40 and may be in contact with the first and second peripheral impurity regions 5a and 5b. The peripheral interconnection 60 may be disposed on the third peripheral capping pattern 48 and the peripheral plug 63 and may extend in the horizontal direction. In some example embodiments, peripheral interconnection 60 may be formed integrally with peripheral plug 63. For example, the peripheral interconnection 60 may include a barrier layer 61 and a conductive layer 62, and the barrier layer 61 and the conductive layer 62 may extend vertically downward and may form the peripheral plug 63. In some other example embodiments, the peripheral interconnection 60 may not be formed integrally with the peripheral plug 63.

The semiconductor device 100 may further include an insulating pattern 65 disposed between the peripheral interconnections 60. The insulating patterns 65 may spatially separate the peripheral interconnections 60 and may electrically insulate the peripheral interconnections 60 from each other.

The semiconductor device 100 may further include an etch stop layer 68 disposed on the peripheral interconnections 60. The etch stop layer 68 may be formed integrally with the etch stop layer 168 (e.g., see FIGS. 3 and 4B). For example, the etch stop layer 68 may be formed by extending the etch stop layer 168 to the peripheral circuit region PA.

The semiconductor device 100 may further include a peripheral contact plug PCP (or ‘peripheral lower contact plug’) disposed on the peripheral interconnections 60. The peripheral contact plug PCP may penetrate the lower interlayer insulating layer 186 and the etch stop layer 68 and may be in contact with one of the peripheral interconnections 60. The peripheral contact plug PCP may be electrically connected to the first peripheral impurity region 5a or the second peripheral impurity region 5b through the peripheral interconnection 60 and the peripheral plug 63. An upper surface of the peripheral contact plug PCP may be coplanar with upper surfaces of the cell contact plug CCP (e.g., see FIGS. 3 and 4B). The peripheral contact plug PCP may include a barrier layer PCPa and a conductive layer PCPb on the barrier layer PCPa. The barrier layer PCPa and the conductive layer PCPb may include a material the same as or similar to that of the barrier layer CCPa and the conductive layer CCPb of the cell contact plug CCP.

The semiconductor device 100 may include a peripheral interconnection region WS2 disposed on the peripheral contact plug PCP and the peripheral redistribution region RS2 on the peripheral interconnection region WS2 in the peripheral circuit region PA.

The peripheral interconnection region WS2 may be configured as an integrated region electrically connected to the cell interconnection region WS1 through the interface region IA. For example, an upper surface of peripheral interconnection region WS2 may be coplanar with an upper surface of the cell interconnection region WS1 (e.g., see FIGS. 3 and 4A). Similarly, the peripheral redistribution region RS2 may be configured as an integrated region electrically connected to the cell redistribution region RS1 through the interface region IA, and an upper surface of the peripheral redistribution region RS2 may be coplanar with an upper surface of cell redistribution region RS1 (e.g., see FIGS. 3 and 4A). The first and second upper blocking layers 231 and 233 disposed on the cell redistribution region RS1 may extend to a conformal thickness along the peripheral circuit region PA through the interface region IA, and the first and second upper blocking layers 231 and 233 of the cell array region CA may be coplanar with the first and second upper blocking layers 231 and 233 of the peripheral circuit region PA, respectively.

In the peripheral circuit region PA, the first and second upper blocking layers 231 and 233 having a low hydrogen diffusivity may be disposed on a lower surface and an upper surface of the second passivation layer 230, and by going through an annealing process to supply hydrogen from a hydrogen supply material layer to the transistor, the semiconductor device 100 having improved electrical properties and reliability may be provided.

Referring to FIGS. 5 and 17B, similarly to the example described with reference to FIGS. 3 to 4B and 17A, the first and second upper blocking layers 231 and 233 of the peripheral circuit region PA may allow hydrogen derived from the hydrogen supply material layer 221 to be completely supplied and guided to the peripheral transistor through the second hydrogen delivery path P2. Here, hydrogen may be supplied to the peripheral transistor through a redistribution layer 225, a redistribution via 227, an upper interconnection 203, an upper contact plug 201, a plurality of lower interconnections 191, 193, and 195, and a peripheral contact plug PCP. However, the supply of hydrogen is not limited to the path described above and hydrogen may be supplied through various paths. The first and second upper blocking layers 231 and 233 may be configured to inhibit hydrogen included in the hydrogen supply material layer 221 from diffusing upwardly (e.g., in a direction away from the peripheral transistor).

Hereinafter, other component or elements disposed in the peripheral interconnection region WS2 and the peripheral redistribution region RS2 and characteristics thereof may be the same as or similar to the cell interconnection region WS1 and the cell redistribution region RS1 described with reference to FIGS. 3 to 4B, and the detailed descriptions thereof will thus not be provided.

FIGS. 6A and 6B are enlarged diagrams illustrating a portion of the semiconductor device illustrated in FIGS. 3 and 5. FIG. 6A corresponds to region ‘D’ in FIG. 3, and FIG. 6B corresponds to region ‘E’ in FIG. 5.

Referring to FIGS. 6A and 6B, the semiconductor device 200 may be configured the same as or similar to the example described with reference to FIGS. 1 to 5, other than the configuration in which blocking layers 211 and 213 may be further included between the interconnection region WS and the redistribution region RS.

Referring to FIGS. 6A and 6B, the intermediate blocking layers 211 and 213 on (e.g., covering) at least one of an upper surface or a lower surface of the first passivation layer 210 between the interconnection region WS and the redistribution region RS on the cell region CA and the peripheral circuit region PA may be further disposed.

The intermediate blocking layers 211 and 213 may include, for example, a first intermediate blocking layer 211 on (e.g., covering) a lower surface of the first passivation layer 210 and a second intermediate blocking layer 213 on (e.g., covering) an upper surface of the first passivation layer 210. The first and second intermediate blocking layers 211 and 213 may be formed to have a conformal thickness throughout the cell region CA and the peripheral circuit region PA, and upper surfaces of the first and second intermediate blocking layers 211 and 213 on the cell region CA may be coplanar with upper surfaces of the first and second intermediate blocking layers 211 and 213 on the peripheral circuit region PA, respectively.

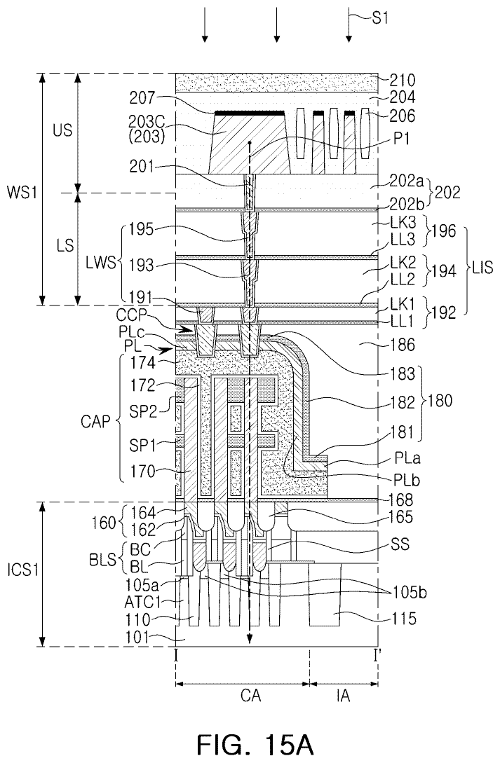

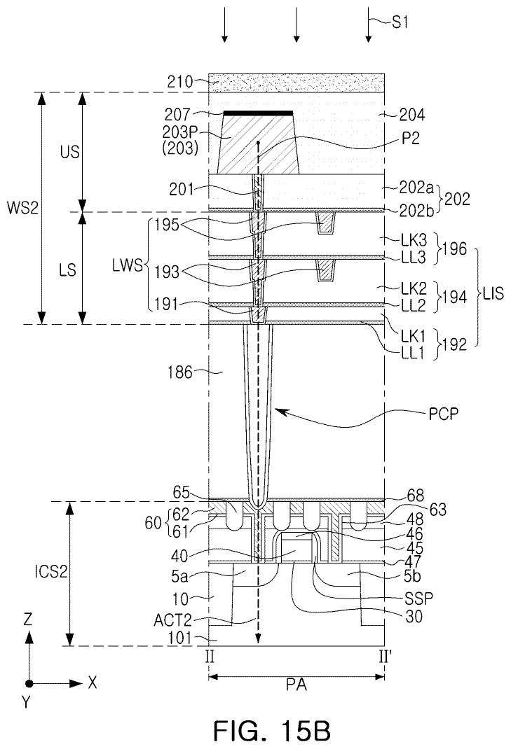

Referring to FIGS. 6A, 6B, 15A, and 15B together, when the first and second intermediate blocking layers 211 and 213 are further disposed on a lower surface and an upper surface of the first passivation layer 210, respectively, during a first annealing process S1, hydrogen contained in the upper interlayer insulating layers 202 and 204 may be completely supplied and guided to the cell transistor and/or peripheral transistor through the first hydrogen delivery path P1 and/or the second hydrogen delivery path P2. For example, hydrogen may be supplied to the cell transistor and/or the peripheral transistor through an upper interconnection 203, an upper contact plug 201, a plurality of lower interconnections 191, 193, and 195, and a lower contact plug CCP and/or a peripheral contact plug PCP, but the supply of hydrogen is not limited to these paths, and hydrogen may be supplied through various paths. The first and second intermediate blocking layers 211 and 213 may be configured to inhibit hydrogen included in the upper interlayer insulating layers 202 and 204 from diffusing upwardly (e.g., in a direction away from the cell transistor and/or the peripheral transistor). For example, the first and second intermediate blocking layers 211 and 213 may include a material that has a low hydrogen diffusivity (e.g., aluminum oxide (AlOx)).

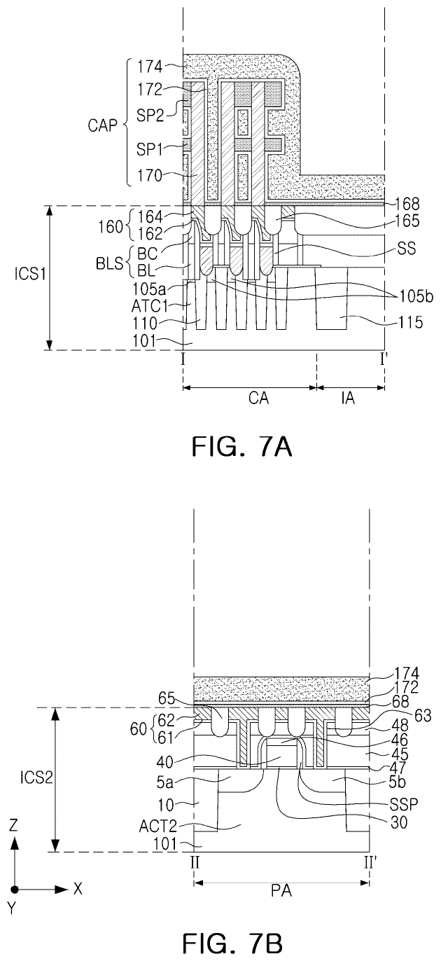

FIGS. 7A to 17B are vertical cross-sectional diagrams illustrating processes of a method of manufacturing a semiconductor device in order according to some example embodiments.

Referring to FIGS. 7A and 7B, in a cell region CA, a data storage structure CAP may be formed on a cell integrated circuit structure ICS1 including a substrate 101, a wordline, and a bitline structure BLS.

The data storage structure CAP may be formed by forming first electrode structures 170, supporter layers SP1 and SP2, a dielectric layer 172, and second electrode structures 174 in order. For example, the data storage structure CAP may be formed by conformally forming an etch stop layer 168, 68 on the cell integrated circuit structure ICS1 and the peripheral integrated circuit structure ICS2, forming first electrode structures 170 by filling a plurality of holes penetrating the mold layer (not illustrated) and supporter layers SP1 and SP2 with a conductive material, conformally forming the dielectric layer 172 along a surface of the first electrode structures 170 and the supporter layers SP1 and SP2 by selectively removing the mold layer (not illustrated), and forming a second electrode structure 174 on (e.g., covering) the dielectric layer 172 throughout the cell region CA, the interface region IA and the peripheral circuit region PA.

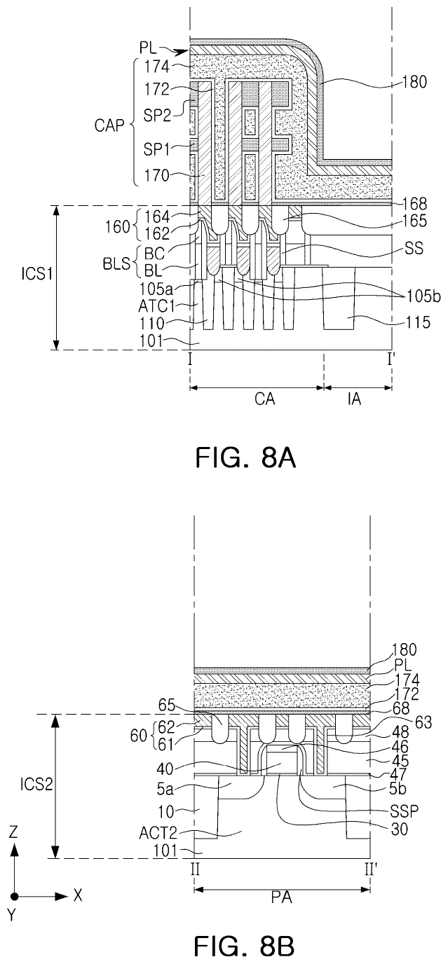

Referring to FIGS. 8A and 8B, a plate layer PL and a blocking layer 180 may be formed on the data storage structure CAP. The plate layer PL may be on (e.g., may cover) the data storage structure CAP and may extend from the cell region CA to the peripheral circuit region PA. The blocking layer 180 may be on (e.g., may cover) the plate layer PL and may extend from the cell region CA to the peripheral circuit region PA. The blocking layer 180 may be formed to have a thickness less than a thickness of the plate layer PL (e.g., in the Z-direction).

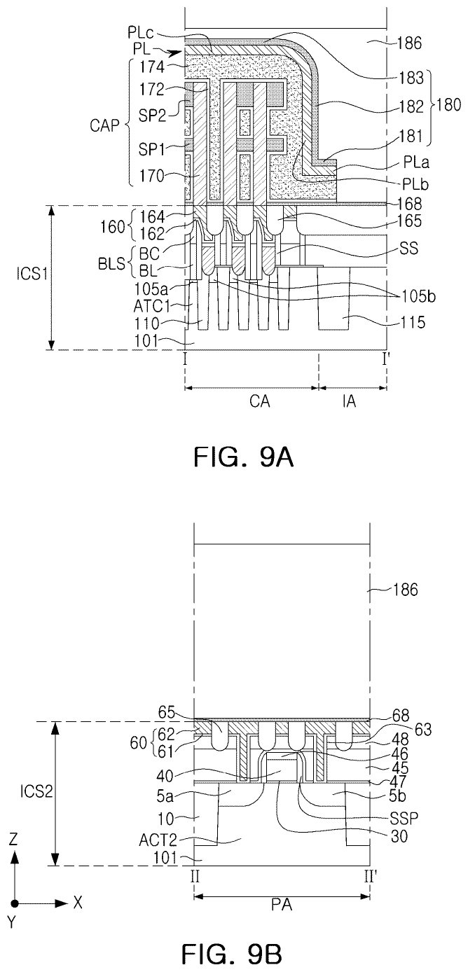

Referring to FIGS. 9A and 9B, the dielectric layer 172, the second electrode structure 174, the plate layer PL, and the blocking layer 180 in the peripheral circuit region PA may be removed by an etching process. The etched dielectric layer 172, the second electrode structure 174, the plate layer PL and the blocking layer 180 may be disposed in the cell region CA, and may also be disposed in the interface region IA in some example embodiments. The etched plate layer PL may include a lower portion PLa, an intermediate portion PLb, and an upper portion PLc. The etched blocking layer 180 may include a lower portion 181, an intermediate portion 182, and an upper portion 183. Side surfaces of the lower portion PLa of the plate layer PL and the lower portion 181 of the blocking layer 180 may be coplanar with the dielectric layer 172 and the second electrode structure 174.

The lower interlayer insulating layer 186 may be formed on the etch stop layer 168, the etch stop layer 68 and the blocking layer 180. The lower interlayer insulating layer 186 may completely cover the blocking layer 180 and may be in contact with the lower portion PLa of the plate layer PL and the lower portion 181 of the blocking layer 180. The lower interlayer insulating layer 186 may also be in contact with the dielectric layer 172 and the second electrode structure 174.

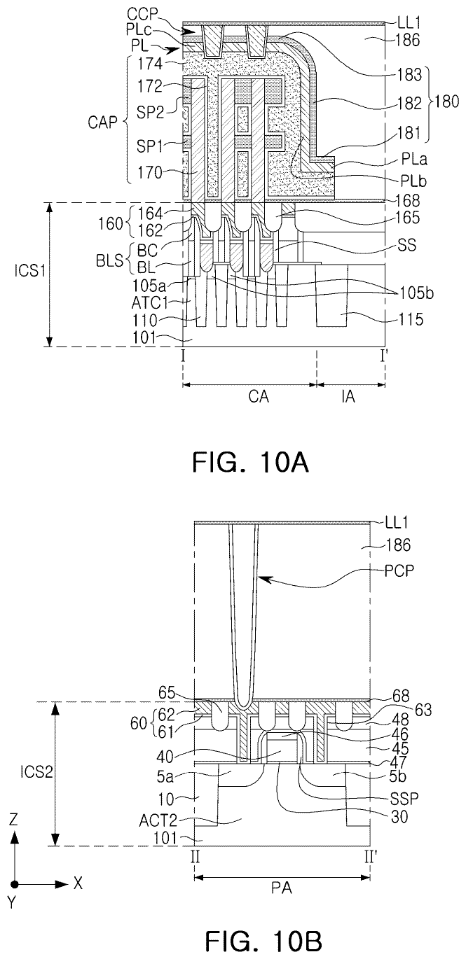

Referring to FIGS. 10A and 10B, a cell contact plug CCP may be formed in the cell region CA and a peripheral contact plug PCP may be formed in the peripheral circuit region PA.

In the cell region CA, first contact holes penetrating at least a portion of the lower interlayer insulating layer 186 and exposing at least a portion of the second electrode structure 174 of the data storage structure CAP may be formed, and a cell contact plug CCP may be formed by filling the first contact holes with a conductive material. The cell contact plug CCP may be electrically connected to the data storage structure CAP on the cell region CA.

In the peripheral circuit region PA, second contact holes penetrating the lower interlayer insulating layer 186 and the etch stop layer 68 and exposing at least a portion of the conductive layer 62 of the peripheral interconnection 60 may be formed, and a peripheral contact plug PCP may be formed by filling the second contact holes with a conductive material. The peripheral contact plug PCP may be electrically connected to the first peripheral impurity region 5a or the second peripheral impurity region 5b through the conductive layer 62 on the peripheral circuit region PA. The cell contact plug CCP and the peripheral contact plug PCP may be formed through a deposition process such as sputtering or MOCVD.

Thereafter, an upper surface of the lower interlayer insulating layer 186 may be exposed through a planarization process such as chemical mechanical polishing (CMP), and a surface treatment process may be performed on the exposed upper surface. The surface treatment process may be performed through at least one of gas treatment including NH₃, H₂, Ar, N₂, and SiH₄, direct (or remote) plasma treatment, or UV treatment.

Thereafter, the first interfacial layer LL1 may be formed on the lower interlayer insulating layer 186. The first interfacial layer LL1 may include hydrogenated silicon oxycarbide (e.g., SiOCH).

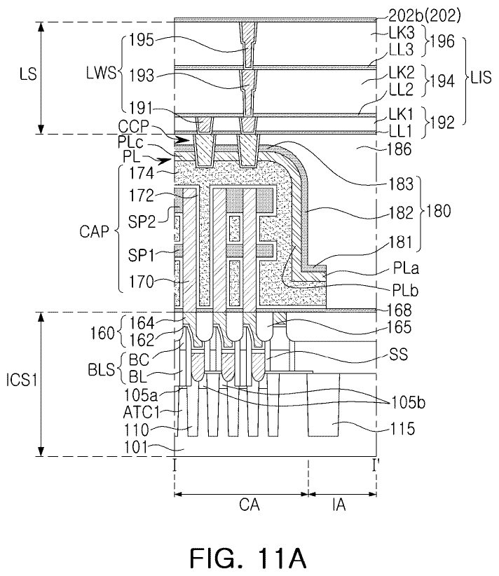

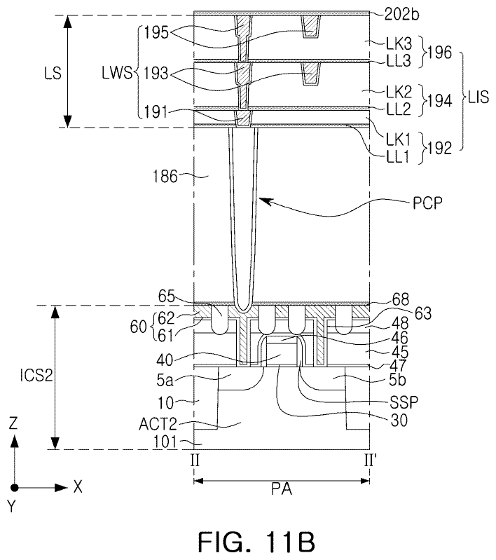

Referring to FIGS. 11A and 11B, a lower structure LS including a lower interconnection structure LWS including a plurality of lower interconnections 191, 193, and 195 and a lower insulating structure LIS including a plurality of insulating patterns 192, 194, and 196 may be formed on the first interfacial layer LL1.

The first low-K layer LK1 may be formed on the first interfacial layer LL1. A mask pattern may be formed on the first low-K layer LK1, and recess regions exposing upper surfaces of the cell contact plug CCP and the peripheral contact plug PCP may be formed through an etching process. Here, the first interfacial layer LL1 may work as an etch stop film. Thereafter, the first lower interconnection 191 may be formed in the recess regions by a damascene process using copper (Cu) or tungsten (W).

Thereafter, a second interfacial layer LL2 and a second low-K layer LK2 may be formed on the first low-K layer LK1, and a second lower interconnection 193 may be formed by performing a damascene process. Here, at least a portion of the second lower interconnections 193 may be formed by a dual damascene process, and accordingly, an upper width of the second lower interconnections 193 may be greater than a lower width.

Similarly, a third interfacial layer LL3 and a third low-K layer LK3 may be formed on the second low-K layer LK2, and a third lower interconnection 195 may be formed by performing the dual damascene process on at least a portion thereof. Accordingly, an upper width of at least a portion of the third lower interconnection 195 may be greater than a lower width.

Thereafter, an upper interfacial layer 202b on (e.g., covering) the third lower interconnection 195 may be formed. The upper interfacial layer 202b may be formed by a process corresponding to the process by which the first, second, and third interfacial layers LL1, LL2, and LL3 are formed.

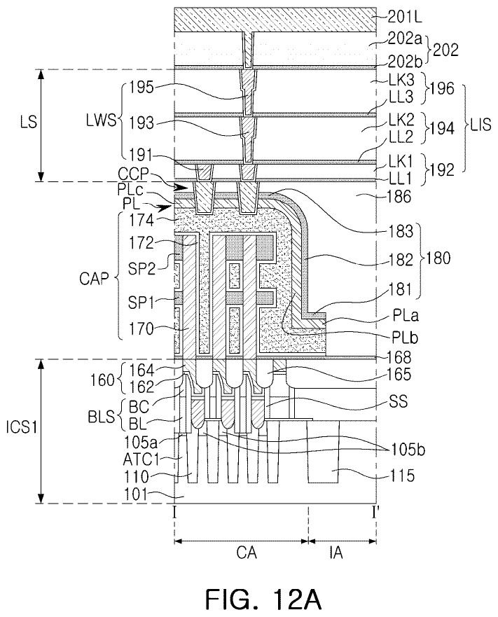

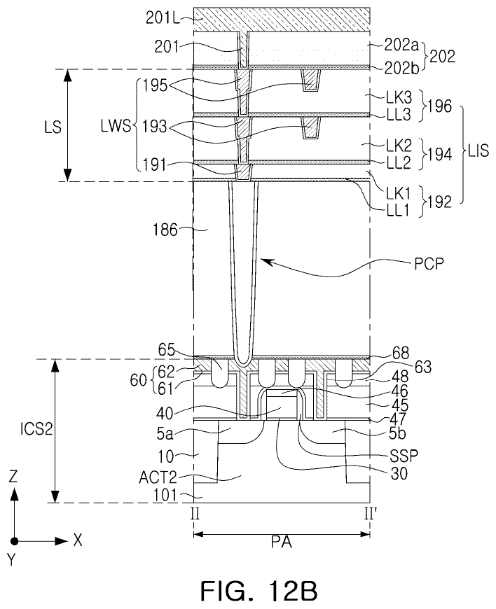

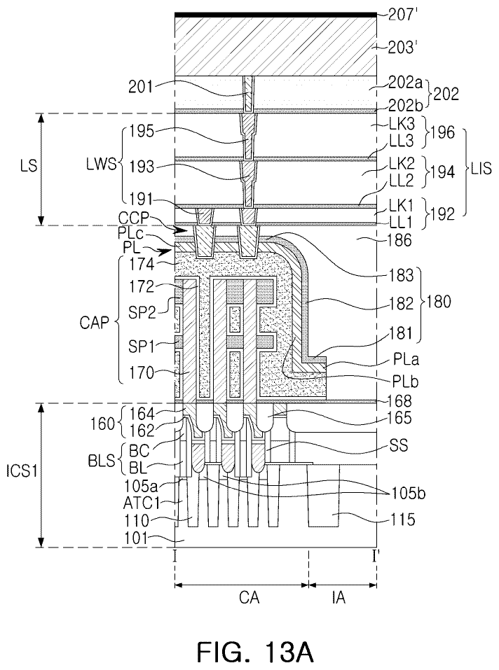

Referring to FIGS. 12A and 12B, the first upper insulating layer 202a may be formed on the upper interfacial layer 202b.

Thereafter, a mask pattern may be formed on the first upper insulating layer 202a, and contact holes exposing an upper surface of the third lower interconnection 195 may be formed through an etching process.

Thereafter, a preliminary upper contact layer 201L filling the contact holes may be formed. The preliminary upper contact layer 201L may include a vertical portion filling the contact holes and may be in contact with an upper surface of the third lower interconnection 195 and a horizontal portion on the upper interlayer insulating layer 202. Here, the vertical portion and the horizontal portion may be formed integrally.

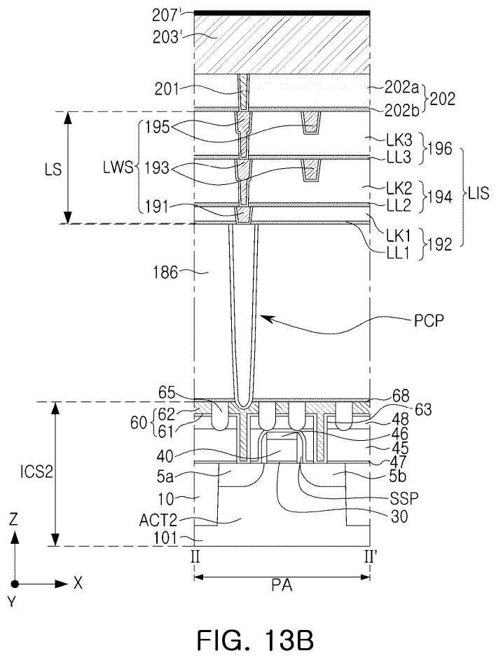

Referring to FIGS. 13A and 13B, an upper contact plug 201 may be formed through a planarization process, and a preliminary upper interconnection 203′ may be formed on the upper interlayer insulating layer 202 and the upper contact plug 201.

Through the planarization process, an upper surface of the first upper insulating layer 202a may be exposed and accordingly, the upper contact plug 201 may be formed. Accordingly, the upper surface of the first upper insulating layer 202a and the upper surface of the upper contact plug 201 may be substantially coplanar with each other.

Thereafter, a preliminary upper interconnection 203′ may be formed on the upper interlayer insulating layer 202 and the upper contact plug 201. If desired, an upper pad material layer 207′ may be further formed on the preliminary upper interconnection 203′. The preliminary upper interconnection 203′ and the upper pad material layer 207′ may be formed by a deposition process. For example, the preliminary upper interconnection 203′ may include Al, and the upper pad material layer 207 may include TiN.

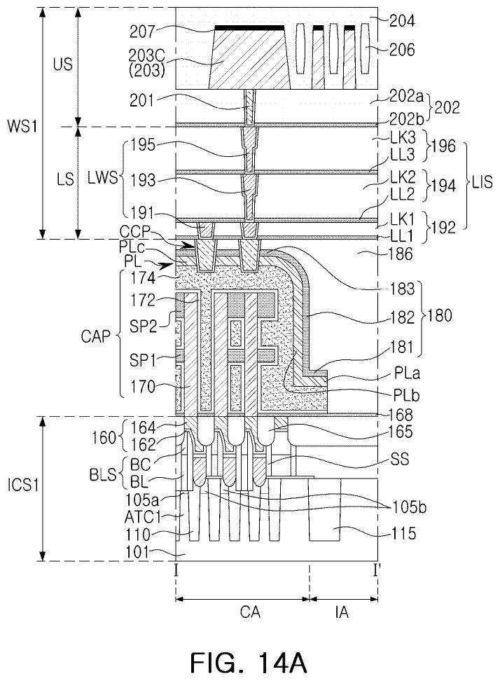

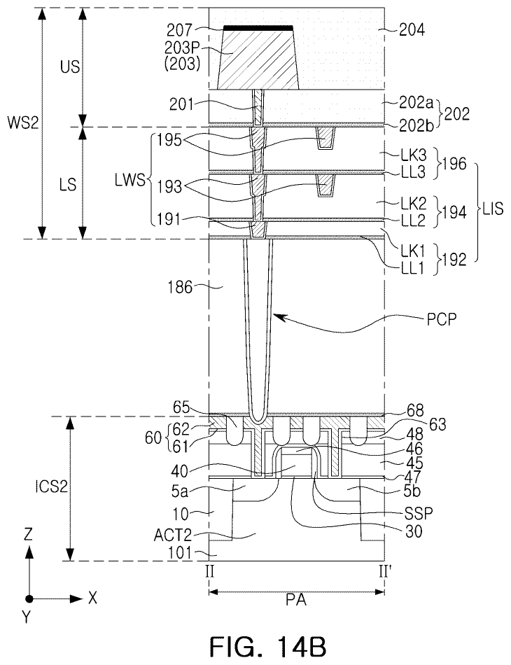

Referring to FIGS. 14A and 14B, an upper interconnection 203 including a cell upper interconnection 203C on the cell region CA and a peripheral upper interconnection 203P on the peripheral circuit region PA may be formed through an etching process. Thereafter, by forming a second upper interlayer insulating layer 204 surrounding the upper interconnection 203, the interconnection region WS may be formed.

A mask pattern may be formed on the preliminary upper interconnection 203′, and a plurality of open regions exposing at least a portion of an upper surface of the first upper insulating layer 202a may be formed through an etching process. Through the etching process, a cell upper interconnection 203C on the cell region CA and a peripheral upper interconnection 203P on the peripheral circuit region PA may be formed. Here, an upper width of upper interconnection 203 may be smaller than a lower width.

Thereafter, a second upper interlayer insulating layer 204 filling the plurality of open regions and surrounding the upper interconnection 203 may be formed. The second upper interlayer insulating layer 204 may be formed by a process corresponding to the process of forming the first upper insulating layer 202a. In the process in which the second upper interlayer insulating layer 204 fills the plurality of open regions, a plurality of air gaps 206 may be formed.

Referring to FIGS. 15A and 15B, a first passivation layer 210 may be formed on the interconnection region WS, and a first annealing process S1 may be performed.

A first passivation layer 210 may be formed on the second upper interlayer insulating layer 204 of the interconnection region WS.

Thereafter, the first annealing process S1 may be performed. The first annealing process S1 may be a heat treatment process performed for tens to hundreds of minutes at a temperature in a range of about 300° C. to 500° C. Heat from the first annealing process S1 may be applied to an upper surface of the first passivation layer 210.

By the first annealing process S1, hydrogen contained in the second upper interlayer insulating layer 204 may be supplied to the substrate 101 through the first hydrogen delivery path P1 and/or the second hydrogen delivery path P2. Referring to FIGS. 6A, 6B, 15A, and 15B, by further forming blocking layers 211 and 213 on a lower surface and an upper surface of the first passivation layer 210, the amount of hydrogen supplied to the substrate 101 through the first hydrogen delivery path P1 and/or the second hydrogen delivery path P2 may increase.

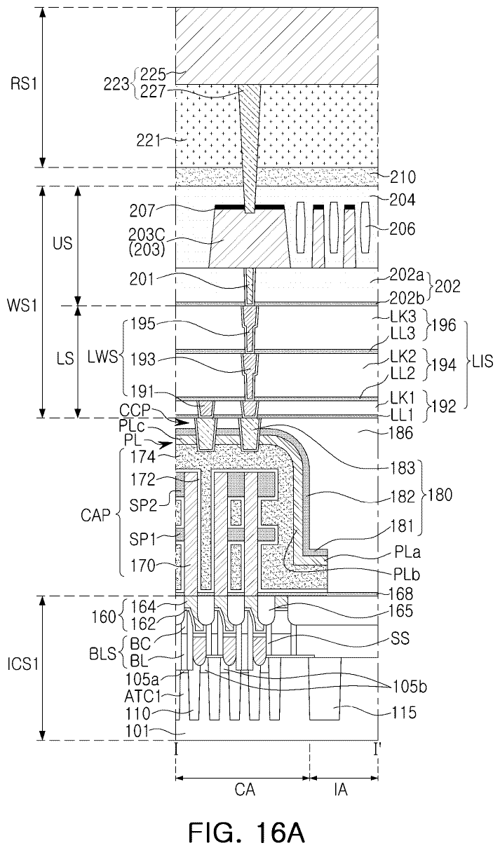

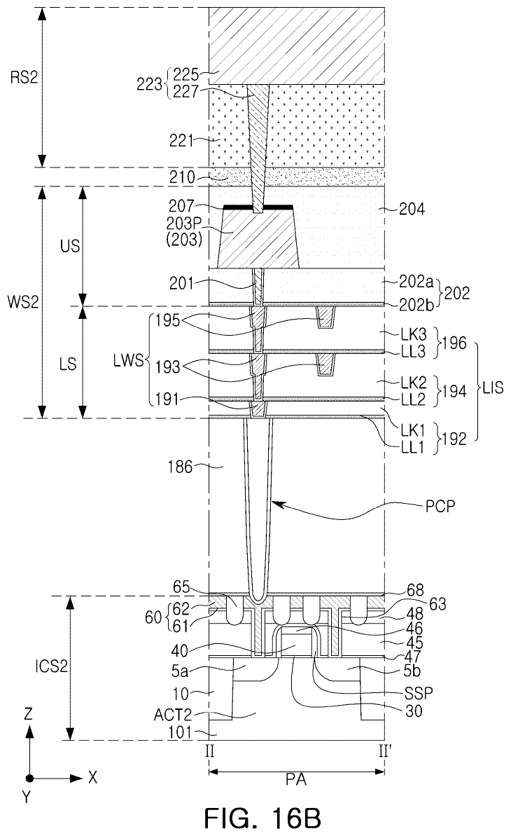

Referring to FIGS. 16A and 16B, after going through the first annealing process S1 according to FIGS. 15A and 15B, a redistribution region RS may be formed on the first passivation layer 210.

A hydrogen supply material layer 221 may be formed on the first passivation layer 210.

Thereafter, a mask pattern may be formed on the hydrogen supply material layer 221, and a through-hole penetrating the hydrogen supply material layer 221, the first passivation layer 210, the second upper interlayer insulating layer 204, and the upper pad 207 and exposing at least a portion of an upper region of the upper interconnection 203 may be formed through an etching process. Thereafter, a redistribution via 227 may be formed by filling the through-hole with a conductive material.

Thereafter, a redistribution layer 225 may be formed on the hydrogen supply material layer 221 and the redistribution via 227, thereby forming a redistribution structure 223.

Referring to FIGS. 17A and 17B, the first upper blocking layer 231, the second passivation layer 230, and the second upper blocking layer 233 may be formed in order on the redistribution region RS, and the second annealing process S2 may be further performed.

A first upper blocking layer 231, a second passivation layer 230, and a second upper blocking layer 233 may be formed in order on the redistribution layer 225 of the redistribution region RS. The first upper blocking layer 231 may be formed on the redistribution layer 225 using atomic layer deposition (ALD). Thereafter, the second passivation layer 230 may be formed on the first upper blocking layer 231 by a process corresponding to a process of forming the first passivation layer 210, and the second upper blocking layer 233 may be formed on the second passivation layer 230. The second upper blocking layer 233 may be formed by a process corresponding to the process of forming the first upper blocking layer 231. The first and second upper blocking layers 231 and 233 may be formed to have a thickness less than a thickness of the second passivation layer 230 (e.g., in the Z-direction).

Thereafter, a second annealing process S2 may be further performed. The second annealing process S2 may be configured as a heat treatment process performed for tens to hundreds of minutes at a temperature in a range of about 300° C. to 500° C., similarly to the first annealing process S1. Heat from the second annealing process S2 may be applied to an upper surface of the second upper blocking layer 233.

By the second annealing process S2, hydrogen contained in the hydrogen supply material layer 221 may be supplied to the substrate 101 through the first hydrogen delivery path P1 in the cell region CA and the second hydrogen delivery path P2 in the peripheral circuit region PA. In some example embodiments, by further disposing the first and second upper blocking layers 231 and 233 on a lower surface and an upper surface of the second passivation layer 230, respectively, hydrogen in the hydrogen supply material layer 221 may be prevented from diffusing in the opposite direction of the first and second hydrogen delivery paths P1 and P2.

Thereafter, although not illustrated, a third passivation layer 240 may be formed on the second upper blocking layer 233 (e.g., see FIG. 5). If desired, in the peripheral circuit region PA, an external connection terminal including a connection via 243 penetrating the second and third passivation layers 230 and 240 and the first and second upper blocking layers 231 and 233 and in contact with the redistribution layer 225, and a connection pad 241 on the connection via 243 may be formed (e.g., see FIG. 5). The external connection terminal may transmit a signal received from an external entity to the semiconductor device 100.

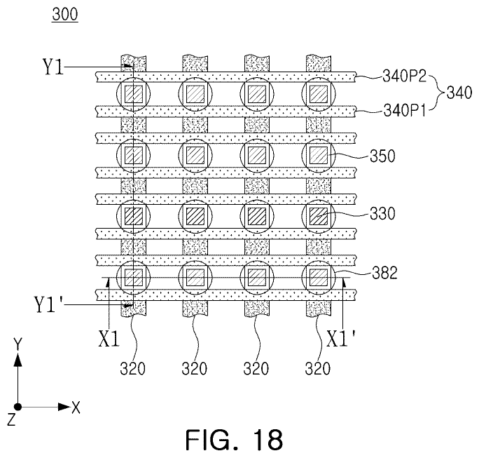

FIG. 18 is a layout diagram illustrating a semiconductor device according to some example embodiments.

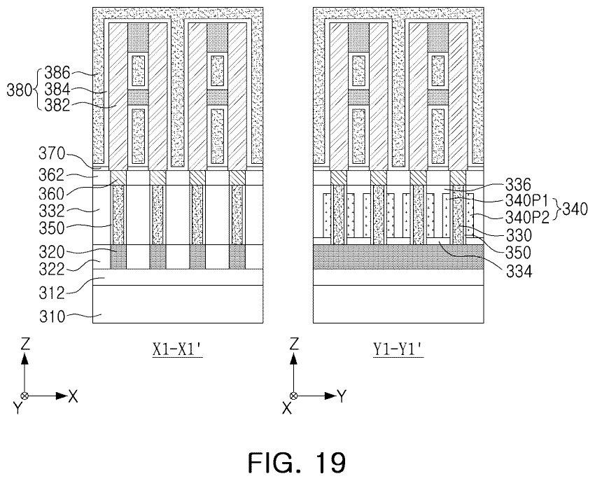

FIG. 19 is a cross-sectional diagram illustrating a semiconductor device according to some example embodiments, taken along lines X1-X1′ and Y1-Y1′ in FIG. 18.

Referring to FIGS. 18 and 19, the semiconductor device 300 may include a substrate 310, a plurality of first conductive lines 320, a channel layer 330, a gate electrode 340, a gate insulating layer 330, and a data storage structure 380. The semiconductor device 300 may be a memory device including a vertical channel transistor (VCT). The vertical channel transistor may refer to a structure in which a channel length of the channel layer 330 may extend from the substrate 310 in the vertical direction (e.g., the Z-direction).

A lower insulating layer 312 may be disposed on the substrate 310, and a plurality of first conductive lines 320 may be spaced apart from each other in the first direction (X-direction) and may extend in the second direction (Y-direction) on the lower insulating layer 312. The plurality of first insulating patterns 322 may be disposed to fill a space between the plurality of first conductive lines 320 on the lower insulating layer 312. The plurality of first insulating patterns 322 may extend in the second direction (Y-direction), and upper surfaces of the plurality of first insulating patterns 322 may be disposed on the same level as upper surfaces of the plurality of first conductive lines 320. The plurality of first conductive lines 320 may function as a bitline of the semiconductor device 300.

In some example embodiments, the plurality of first conductive lines 320 may include doped polysilicon, metal, conductive metal nitride, conductive metal silicide, conductive metal oxide, or combinations thereof. For example, the plurality of first conductive lines 320 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof, but the present disclosure is not limited thereto. The plurality of first conductive lines 320 may include a single layer or multiple layers formed of the aforementioned materials. In some example embodiments, the plurality of first conductive lines 320 may include a two-dimensional semiconductor material, for example, the two-dimensional semiconductor material may include graphene, carbon nanotube, or a combination thereof.

The channel layers 330 may be arranged in the form of a matrix spaced apart from each other in the first direction (X-direction) and the second direction (Y-direction) on the plurality of first conductive lines 320. The channel layer 330 may have a first width in the first direction (X-direction) and a first length in the third direction (Z-direction), and the first length may be greater than the first width. For example, the first length may be in a range of about 2 to 10 times greater than the first width, but the present disclosure is not limited thereto. A bottom portion of the channel layer 330 may function as a first source/drain region (not illustrated), an upper portion of the channel layer 330 may function as a second source/drain region (not illustrated), and a portion of the channel layer 330 between the first and second source/drain regions may function as a channel region (not illustrated). The first source/drain region and the second source/drain region may be vertically spaced apart from each other, and the channel region may be a vertical channel region.

In some example embodiments, the channel layer 330 may include an oxide semiconductor, for example, the oxide semiconductor may include InxGayZnzO, InxGaySizO, InxSnyZnzO, InxZnyO, ZnxO, ZnxSnyO, ZnxOyN, ZrxZnySnzO, SnxO, HfxInyZnzO, GaxZnySnzO, Alx ZnySnzO, YbxGayZnzO, InxGayO, or a combination thereof. The channel layer 330 may include a single layer or multiple layers formed of the oxide semiconductor. In some example embodiments, the channel layer 330 may have a bandgap energy greater than that of silicon. For example, the channel layer 330 may have a bandgap energy of about 1.5 eV to 5.6 eV. For example, the channel layer 330 may have optimal channel performance when having a bandgap energy of about 2.0 eV to 4.0 eV. For example, the channel layer 330 may be polycrystalline or amorphous, but the present disclosure is not limited thereto. In some example embodiments, the channel layer 330 may include a two-dimensional semiconductor material, for example, the two-dimensional semiconductor material may include graphene, carbon nanotube (carbon nanotube), or a combination thereof.

The gate electrode 340 may extend in the first direction (X-direction) on both (i.e., opposing) sidewalls of the channel layer 330. The gate electrode 340 may include a first sub-gate electrode 340P1 opposing a first sidewall of the channel layer 330, and a second sub-gate electrode 340P2 opposing a second sidewall opposite to the first sidewall of the channel layer 330. As the channel layer 330 is disposed between the first sub-gate electrode 340P1 and the second sub-gate electrode 340P2, the semiconductor device 300 may have a dual gate transistor structure. However, the present disclosure is not limited thereto, and the second sub-gate electrode 340P2 may not be provided, and only the first sub-gate electrode 340P1 opposing the first sidewall of the channel layer 330 may be formed such that a single gate transistor structure may be implemented.

The gate electrode 340 may include doped polysilicon, metal, conductive metal nitride, conductive metal silicide, conductive metal oxide, or a combination thereof. For example, the gate electrode 340 may be formed of doped polysilicon, Al, Cu, Ti, Ta, Ru, W, Mo, Pt, Ni, Co, TiN, TaN, WN, NbN, TiAl, TiAIN, TiSi, TiSiN, TaSi, TaSiN, RuTiN, NiSi, CoSi, IrOx, RuOx, or a combination thereof, but the present disclosure is not limited thereto.

The gate insulating layer 350 may surround a sidewall of the channel layer 330 and may be interposed between the channel layer 330 and the gate electrode 340. For example, as illustrated in FIG. 19, the entire sidewall of the channel layer 330 may be surrounded by the gate insulating layer 350, and a portion of the sidewall of the gate electrode 340 may be in contact with the gate insulating layer 350. In other example embodiments, the gate insulating layer 350 may extend in the direction in which the gate electrode 340 extends (i.e., the first direction (X-direction)), and among the sidewalls of the channel layer 330, only the two sidewalls facing the gate electrode 340 may be in contact with the gate insulating layer 350.

In some example embodiments, the gate insulating layer 350 may be formed of a silicon oxide film, a silicon oxynitride film, a high-κ film having a dielectric constant higher than that of the silicon oxide film, or a combination thereof. The high-κ film may be formed of metal oxide or metal oxynitride. For example, a high-κ film usable as a gate insulating layer 350 may be formed of HfO2, HfSiO, HfSiON, HfTaO, HfTiO, HfZrO, ZrO2, Al2O3, or a combination thereof, but the present disclosure is not limited thereto.

The plurality of second insulating patterns 332 may extend in the second direction (Y-direction) on the plurality of first insulating patterns 322, and the channel layer 330 among the plurality of second insulating patterns 332 may be disposed between two adjacent second insulating patterns 332. Also, between two adjacent second insulating patterns 332, the first filling layer 334 and the second filling layer 336 may be disposed in a space between two adjacent channel layers 330. The first filling layer 334 may be disposed in a bottom portion of a space between two adjacent channel layers 330, and the second filling layer 336 may be formed to fill the other portion of the space between two adjacent channel layers 330 on the first filling layer 334. An upper surface of the second filling layer 336 may be disposed on the same level as an upper surface of the channel layer 330, and the second filling layer 336 may be on (e.g., may cover) an upper surface of the gate electrode 340. In other example embodiments, the plurality of second insulating patterns 332 may be formed as a material layer continuous with the plurality of first insulating patterns 322, or the second filling layer 336 may be formed as a material layer continuous with the first filling layer 334.

The storage contact 360 may be disposed on the channel layer 330. The storage contact 360 may be disposed to vertically overlap the channel layer 330, and the storage contacts 360 may be arranged in a matrix form by being spaced apart from each other in the first direction (X-direction) and the second direction (Y-direction). The storage contact 360 may be formed of doped polysilicon, Al, Cu, Ti, Ta, Ru, W, Mo, Pt, Ni, Co, TiN, TaN, WN, NbN, TiAl, TiAIN, TiSi, TiSiN, TaSi, TaSiN, RuTiN, NiSi, CoSi, IrOx, RuOx, or a combination thereof, but the present disclosure is not limited thereto. The upper insulating layer 362 may surround a sidewall of the storage contact 360 on the plurality of second insulating patterns 332 and the second filling layer 336. As used herein, “an element A overlaps an element B in a vertical direction” (or similar language) means that there is at least one straight line that extends in the vertical direction and intersects both the elements A and B.

The etch stop film 370 may be disposed on the upper insulating layer 362, and the data storage structure 380 may be disposed on the etch stop film 370. The data storage structure 380 may include a first electrode structure 382, a dielectric layer 384, and a plate electrode 386.

The first electrode structure 382 may penetrate the etch stop film 370 and may be electrically connected to an upper surface of the storage contact 360. The first electrode structure 382 may be formed as a pillar type extending in the third direction (Z-direction), but the present disclosure is not limited thereto. In some example embodiments, the first electrode structure 382 may be disposed to vertically overlap the storage contact 360, and the first electrode structures 382 may be arranged in a matrix form by being spaced apart from each other in the first direction (X-direction) and the second direction (Y-direction). In some example embodiments, a landing pad (not illustrated) may be further disposed between the storage contact 360 and the first electrode structure 382, such that the first electrode structure 382 may be arranged in a hexagonal shape.

In some example embodiments, the semiconductor device 300 may further include a plate layer PL and a blocking layer 180 (see FIG. 3) disposed on the data storage structure 380. For example, the plate layer PL may cover the data storage structure 380, and the blocking layer 180 may be disposed to surround a side surface of the plate layer PL. An upper surface of the plate layer PL may be exposed without being completely covered by the blocking layer 180.

According to the aforementioned example embodiments, by disposing a blocking layer on the capacitor, the amount of hydrogen excessively diffusing into the capacitor may be reduced. By additionally disposing a blocking layer in the redistribution region and adding a heat treatment process, structural defects present in the semiconductor device may be effectively reduced.

While the example embodiments have been illustrated and described above, it will be apparent to those skilled in the art that modifications and variations may be made without departing from the scope of the present disclosure as defined by the appended claims.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

What is claimed is:

1. A semiconductor device, comprising:
an integrated circuit structure including conductive regions;
a capacitor including first electrode structures electrically connected to the conductive regions of the integrated circuit structure, a dielectric layer on the first electrode structures, and a second electrode structure on the dielectric layer;
an insulating blocking layer on at least a portion of a surface of the second electrode structure; and
an interconnection region on the insulating blocking layer and including a conductive pattern and an insulating structure,
wherein the insulating structure includes etch stop layers and interlayer insulating layers that are stacked with one another,
wherein at least one of the interlayer insulating layers includes hydrogen, and
wherein the insulating blocking layer includes a different material from the etch stop layers.

2. The semiconductor device of claim 1, wherein the second electrode structure comprises:
an upper portion on upper surfaces of the first electrode structures;
an intermediate portion extending downwardly from an end of the upper portion; and
a lower portion extending from a lower end of the intermediate portion in a direction away from the first electrode structures.

3. The semiconductor device of claim 2, wherein the insulating blocking layer is on an upper surface of the upper portion, a side surface of the intermediate portion, and an upper surface of the lower portion of the second electrode structure.

4. The semiconductor device of claim 3, wherein the semiconductor device further comprises a lower interlayer insulating layer on a side surface of the lower portion of the second electrode structure and on a surface of the insulating blocking layer, and
wherein the insulating structure is on the lower interlayer insulating layer.

5. The semiconductor device of claim 4, wherein the insulating blocking layer is in contact with the upper surface of the upper portion, the side surface of the intermediate portion, and the upper surface of the lower portion of the second electrode structure, and
wherein the lower interlayer insulating layer is in contact with the side surface of the lower portion of the second electrode structure and the insulating blocking layer.

6. The semiconductor device of claim 4, wherein, in a cross-sectional view, the side surface of the lower portion of the second electrode structure is coplanar with a side surface of a lower portion of the insulating blocking layer, and
wherein the lower portion of the insulating blocking layer is on the upper surface of the lower portion of the second electrode structure.

7. The semiconductor device of claim 4, wherein the lower interlayer insulating layer includes hydrogen, and
wherein the insulating blocking layer is configured to inhibit the hydrogen included in the lower interlayer insulating layer from diffusing to the capacitor.

8. The semiconductor device of claim 1, wherein the second electrode structure comprises:
a first electrode material layer on side surfaces of the first electrode structures and upper surfaces of the first electrode structures; and
a second electrode material layer on the first electrode material layer.

9. The semiconductor device of claim 8, wherein the insulating blocking layer is on at least a portion of a surface of the second electrode material layer, and
wherein the insulating blocking layer has a thickness that is less than a thickness of the second electrode material layer.

10. The semiconductor device of claim 9, wherein the second electrode material layer includes tungsten (W), and
wherein the insulating blocking layer includes aluminum oxide (AlOx).

11. The semiconductor device of claim 1, wherein the insulating blocking layer is configured to inhibit the hydrogen included in the at least one of the interlayer insulating layers from diffusing to the capacitor.

12. The semiconductor device of claim 11, wherein the etch stop layers include at least one of silicon nitride, silicon carbonitride, or hydrogenated silicon oxycarbide, and
wherein the insulating blocking layer includes aluminum oxide (AlOx).

13. A semiconductor device, comprising:
a capacitor;
a lower interlayer insulating layer on the capacitor;
a lower contact extending into the lower interlayer insulating layer and electrically connected to the capacitor;
an interconnection region on the lower contact and the lower interlayer insulating layer, the interconnection region including an insulating structure and an interconnection structure in the insulating structure, wherein the insulating structure includes etch stop layers and first interlayer insulating layers that are stacked with one another;
a first passivation layer on the interconnection region;
a redistribution region on the first passivation layer and including a second interlayer insulating layer and a redistribution structure on the second interlayer insulating layer;
a second passivation layer on the redistribution region;
an upper passivation layer on the second passivation layer; and
an upper blocking layer on at least one of an upper surface or a lower surface of the second passivation layer.

14. The semiconductor device of claim 13, wherein the second interlayer insulating layer is a hydrogen supply material layer, and
wherein the upper blocking layer is configured to inhibit hydrogen included in the hydrogen supply material layer from diffusing upwardly.

15. The semiconductor device of claim 13, wherein a hydrogen diffusivity of the upper blocking layer is lower than a hydrogen diffusivity of the second passivation layer.

16. The semiconductor device of claim 13, further comprising:
an intermediate blocking layer on at least one of an upper surface or a lower surface of the first passivation layer,
wherein at least one of the first interlayer insulating layers includes hydrogen, and
wherein the intermediate blocking layer is configured to inhibit the hydrogen included in the at least one of the first interlayer insulating layers from diffusing upwardly.

17. The semiconductor device of claim 16, wherein the upper blocking layer and the intermediate blocking layer include aluminum oxide (AlOx).

18. A semiconductor device, comprising:
a substrate including a cell array region and a peripheral circuit region;
a lower blocking layer in contact with at least a portion of a side surface of a capacitor, wherein the capacitor is on the cell array region of the substrate;
a peripheral transistor on the peripheral circuit region of the substrate;
a lower interlayer insulating layer on the lower blocking layer and the peripheral transistor;
a cell lower contact extending into the lower interlayer insulating layer and electrically connected to the capacitor;
a peripheral lower contact extending into the lower interlayer insulating layer and electrically connected to the peripheral transistor;
an interconnection region on the lower interlayer insulating layer, the interconnection region comprising:
a lower structure including a lower insulating structure and lower conductive patterns in the lower insulating structure, wherein the lower insulating structure includes etch stop layers and low-K layers alternately stacked on the cell lower contact, the peripheral lower contact, and the lower interlayer insulating layer; and
an upper structure including an upper interlayer insulating layer on the lower structure and an upper conductive pattern in the upper interlayer insulating layer, wherein the upper conductive pattern is electrically connected to the lower conductive patterns,
a first passivation layer on the interconnection region;
a redistribution region on the first passivation layer, the redistribution region comprising:
a hydrogen supply material layer on the first passivation layer; and
a redistribution structure including a redistribution layer on the hydrogen supply material layer and a redistribution via extending into the hydrogen supply material layer, the first passivation layer, and the upper interlayer insulating layer, wherein the redistribution via electrically connects the redistribution layer to the upper conductive pattern,
a second passivation layer on the redistribution region;
an upper passivation layer on the second passivation layer; and
an upper blocking layer on at least one of an upper surface or a lower surface of the second passivation layer and extending on the cell array region and the peripheral circuit region.

19. The semiconductor device of claim 18, wherein the lower blocking layer comprises:
an upper portion on an upper surface of the capacitor;
an intermediate portion extending downwardly from an end of the upper portion along the side surface of the capacitor; and
a lower portion extending horizontally from a lower end of the intermediate portion.

20. The semiconductor device of claim 18, wherein the lower blocking layer and the upper blocking layer include a different material from the etch stop layers.
